(19) United States
(12) Patent Application Publication
(10) Pub. No.: US 2009/0195418 A1
(43) Pub. Date: Aug. 6, 2009

(54) DATA INPUT DEVICE

(76) Inventor: Eui-Jin OH, Daejeon (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/364,417

(22) Filed: Feb. 2, 2009

Related U.S. Application Data
(63) Continuation of application No. PCT/KR2007/003758, filed on Aug. 3, 2007.

(30) Foreign Application Priority Data
Aug. 4, 2006 (KR) 10-2006-0073805
Aug. 8, 2006 (KR) 10-2006-0074472
Oct. 20, 2006 (KR) 10-2006-0102559
Oct. 23, 2006 (KR) 10-2006-0102732
Oct. 23, 2006 (KR) 10-2006-0102830
Feb. 16, 2007 (KR) 10-2007-0016482
Feb. 16, 2007 (KR) 10-2007-0016503
Jun. 26, 2007 (KR) 10-2007-0062590

(51) Int. Cl. H03K 17/94; H03M 11/00

(52) U.S. Cl. 341/34; 341/22

(57) ABSTRACT

A data input device is disclosed. In one embodiment, the data input device includes a plurality of input keys in which a one-stage input for inputting a first character and a two-stage input for inputting a second character are independently performed, a sensor for sensing the one-stage input and the two-stage input to the input keys, and a controller for extracting the first character or the second character redundantly assigned to the corresponding input key based on the sense result of the sensor from a memory to input the first character or the second character.

### RELATED APPLICATIONS

This application is a continuation application, and claims the benefit under 35 U.S.C. §§ 120 and 365 of PCT Application No. PCT/KR2007/003758, filed on Aug. 3, 2007, which is hereby incorporated by reference.

This application also relates to U.S. patent application Ser. Nos. 12/358,148 and 12/358,161, both filed on Jan. 22, 2009, which are incorporated by reference.

### BACKGROUND OF THE INVENTION

1. Field of the Invention

The present invention relates to a data input device, and more particularly, to a data input device in which a key input method is improved so that a one-stage input and a two-stage input can be independently performed by one input key and in which a combination input, a sequential input, and an event input are additionally performed so that input capacity is maximized and that an input can be rapidly and correctly performed by a limited number of input keys.

2. Description of the Related Technology

Recently, as software, semiconductor technology, and information processing technology have remarkably developed, various information apparatuses such as a mobile telephone and a personal digital assistant (PDA) are gradually miniaturized and multi-functioned. Furthermore, the importance of information storage and communications through an input of characters has increased in the information apparatuses.

### SUMMARY OF CERTAIN INVENTIVE ASPECTS

One aspect of the present invention is a data input device capable of inputting a desired character by minimum input key operations through one-stage input in which characters redundantly assigned to an input key are independently input.

Another aspect of the present invention is a data input device in which consonants and vowels are arranged on a minimum number of input keys with the consonants and vowels in a state where one phoneme is input by one operation (or, in the case of a touch screen or a touch pad, pressure as well as touch is sensed to input two characters in the same position) to easily input characters using fingers without additional tools on a touch screen on which a key pad image is provided.

Another aspect of the present invention is a data input device capable of continuously inputting a consonant and a vowel or a consonant, vowel, and a consonant through the shortest path and continuous operations so that it is minimize input time and to easily, stably, and correctly input characters.

Another aspect of the present invention is a data input device capable of correctly inputting data in a narrow space using an interference phenomenon in which adjacent keys are input together.

Another aspect of the present invention is a data input device in which it is not necessary to perform a repeated input but it is possible to perform a skim input so that it is possible to rapidly input data by performing a connected operation once and a movement range for performing an input is narrow so that it is possible to prevent a user from erroneously performing an input and to correctly input data.

Another aspect of the present invention is a character input device which includes a plurality of input keys in which a one-stage input for inputting a first character and a two-stage input for inputting a second character are independently performed; a sensor for sensing the one-stage input and the two-stage input to the input keys; and a controller for extracting the first character or the second character redundantly assigned to the corresponding input key based on the sense result of the sensor from a memory to input the first character or the second character.

Here, the one-stage input may be a touch input performed by contacting or approaching the input keys, and the two-stage input may be a pressure input in which the input keys move up and down, and the sensor may comprises: a touch sensor for sensing the touch input; and a pressure sensor for sensing the pressure input.

Here, the one-stage input and the two-stage input may be performed by a pressure input determined by the up and down movement distance of the input key or the strength of pressure, and the sensor may be formed of a pressure switch switched in accordance with the movement of the input key or a pressure sensor for sensing pressure applied to the input key.

A multiple input of two or more stages can be performed in the pressure input in accordance with the up and down movement distance of the input key or the strength of pressure.

A clicking unit may be provided in the two-stage pressure input to be distinguished from one-stage pressure input.

The number of input keys may be 13 by adding one key to a 4×3 arrangement method used for a mobile communication terminal.

The plurality of input keys may have a rectangular arrangement pattern composed of two or more rows and columns.

Predetermined consonants and vowels may be simultaneously assigned to the input keys, and a conversion input unit for making a conversion into the vowels by the input keys and the combination input may be further provided, and the conversion input unit may be provided in at least one of inside and outside of the input keys.

The plurality of input keys may be arranged on the circumference of a circle having a predetermined radius.

The input keys may be ring-shaped and integrated.

The two pairs of input keys may be provided on both sides of an input region.

A skim input in which two or more input keys sequentially contact can be performed in the touch input.

One or two or more Korean characters or English characters may be redundantly arranged in each of the plurality of input keys, and continuous consonants or continuous vowels that are frequently used for a character input may be continuously arranged in the input keys.

The plurality of input keys are divided into a consonant input key set to which consonant characters may be assigned and a vowel input key set to which vowel characters are assigned, and the consonant input key set and the vowel input key set may be arranged so that the input keys are sequentially touched in the order of consonant and vowel or of consonant, vowel, and consonant when the skim input is performed.

The plurality of input keys may be divided into a consonant input key set to which consonant characters are assigned and a vowel input key set to which vowel characters are assigned, and the consonant input key set and the vowel input key set may be arranged so that the input keys are sequentially touched in the order of consonant, consonant, and vowel or of vowel, consonant, and consonant when the skim input is performed.

The input key may comprises: a first input key; and a second input key provided to be adjacent to inside or outside of the first input key, and when a combination input of simultaneously selecting the first input key and the second input key within predetermined time is performed, a third character different from the character originally assigned to the corresponding input key is extracted from a memory to be input.

Vowels may be input by the combination input between the first input key and the second input key.

The plurality of sensors may be provided in each of the first input key and the second input key.

The controller may determine only a signal maintained for no less than predetermined time as an effective signal among the sense signals of the first input key and the second input key sensed by the sensors to perform an input.

The two pairs of first input keys, second input keys, and sensors may be provided in the input region.

The data input device may further comprise a conversion input unit provided to be adjacent to the plurality of input keys, so that the controller extract a fourth character from a memory by a sequential input of sequentially selecting the input key and the conversion input unit to input the fourth character.

Here, a first character or a second character may be input by a single input of the input key, and a fourth character may be input by a sequential input in the order of the input key and the conversion input unit, and an input may not be performed by the sequential input in the opposite order.

A first character or a second character may input by a single input of the input key, and a fourth character may be input by a sequential input in the order of the conversion input unit and the input key, and an input may not be performed by the sequential input in the opposite order.

The plurality of input keys may be circularly arranged, and when a circumferential input in which a plurality of input keys are sequentially selected along a circumferential direction is performed, the controller determines only the character assigned to the finally selected input key to be effective so that an input is performed.

The plurality of input keys may be circularly arranged and the data input device may further include second touch sensors for sensing skimming in the radius direction of the input keys so that a first character or a second character be input by the touch input or a pressure input, and a fourth character be input by radius direction touch to the input key.

The direction of the sequential input for inputting the assigned fourth character may be displayed in the input key.

The two pairs of input keys, conversion input units, and sensors may be provided in the input region.

The plurality of input keys may be circularly arranged, and a fifth character may be redundantly assigned to the input key, and when an event input is sensed, the controller extracts the fifth character from a memory to input the fifth character.

The event input may be performed by lifting a finger from a predetermined input key during the skim input so that a touch sense signal is canceled or by continuously generating a touch sense signal to a predetermined input key for no less than predetermined time.

The event input may performed by horizontally pressing a side in the pressure direction of the input key.

The touch sensor may comprise: a first touch sensor for sensing touch to the input key or skimming in a circumferential direction; and a second touch sensor for sensing skimming to the radius direction to the input key, and the controller extracts the first character when the sense signal of the first touch sensor is received and the fifth character determined to be an event input when the sense signal of the second touch sensor is received to input the first character and the fifth character.

The input key may comprise: a circularly arranged first input key; and second input keys provided to be adjacent to the inside or the outside of the first input key.

When a combination input of simultaneously selecting the first input key and the second input key within predetermined time is performed, the controller extracts a third character different from the character originally assigned to the corresponding input key from a memory to input the third character.

The second input key can be moved in a predetermined radial direction and further comprises a movement sensor for sensing the radial movement of the second input key, and the controller extracts a sixth character assigned in the corresponding radial direction where the movement of the second input key is sensed from a memory to input the sixth character.

The touch sensor may be provided to sense touch movement to the radial direction to the second input key, and the controller extracts a sixth character assigned in the corresponding radial direction in the direction of touch movement performed by the second input key from a memory to input the sixth character.

The plurality of two pairs of input keys and sensors may be provided in the input region.

Another aspect of the present invention is a character input device which may comprise: 8 first input keys that are radially arranged on a circle having a predetermined radius in an input region and in which a one-stage input for inputting a first character by touch and a two-stage input for inputting a second character by pressure are independently provided; second input keys provided inside or outside the first input keys; a first input key sensor for sensing the on stage input or the two-stage input; a second input key sensor for sensing the selection of the second input keys; and a controller for extracting the first character or the second character assigned to the corresponding first input keys from a memory based on the sense result of the first input key sensor to input the first character or the second character and for extracting a third character from a memory when sense signals are simultaneously generated from the first input key sensor and the second input key sensor within predetermined time to input the third character.

Here, the third character may be a vowel.

Another aspect of the present invention is a character input device which may comprise; a plurality of first input keys that are radially arranged on a circle having a predetermined radius in an input region and in which a one-stage input for inputting a first character by touch and a two-stage input for inputting a second character by pressure are independently provided; at least one second input keys provided inside or outside the first input keys to input a seventh character by a method of touch and pressure; a first input key sensor for sensing the on stage input or the two-stage input; a second input key sensor for sensing the selection of the second input keys; and a controller for extracting the first character, the second character, or the seventh character assigned to the corresponding first or second key from a memory based on the sense result of the input key sensor to input the first, second, or seventh character.

When a skim input for continuously inputting the plurality of first or second input keys is performed, the controller inputs a character assigned to the corresponding input key by a method of an initial input signal, an input signal maintained for predetermined time, or a canceled input signal.

Another aspect of the present invention is a character input device which may comprise; a plurality of first input keys that are radially arranged on a circle having a predetermined radius in an input region and in which a one-stage input for inputting a first character by touch and a two-stage input for inputting a second character by pressure are independently provided; second input keys provided inside or outside the first input keys; a first input key sensor for sensing the on stage input or the two-stage input; a second input key sensor for sensing the selection of the second input keys; and a controller for extracting the first character or the second character assigned to the corresponding first or second input keys from a memory based on the sense result of the first input key sensor to input the first character or the second character and for assigning a third character when a combination input simultaneously sensed by the first input key sensor and the second input key sensor within predetermined time is performed, wherein the controller inputs a character assigned to the corresponding input key by a method of an initial input signal, an input signal maintained for predetermined time, and a cancelled input signal when a skim input in which the plurality of the first input keys are continuously input is performed.

Here, the number of first input keys may be 8, and the second input key may have 4 input positions.

Another aspect of the present invention is a character input device which may comprise; 8 first input keys radially arranged on a circle having a predetermined radius in an input region; a second input key provided inside or outside the first input keys; an internal input key provided in the center of the circle; a first input key sensor for sensing the selection of the first input keys; a second input key sensor for sensing the selection of the second input keys; an internal input key sensor for sensing the selection of the internal input key; and a controller for extracting a character of the corresponding input key from a memory based on the sense results of the input key sensors to input the character, wherein a multiple stage input can be performed in at least one of the first input key, the second input key, and the internal input key.

Another aspect of the invention is a data input device, comprising: a plurality of input keys in which a one-stage input for inputting a first character and a two-stage input for inputting a second character are independently performed; a sensor configured to sense the one-stage input and the two-stage input to the input keys; and a controller configured to extract the first character or the second character redundantly assigned to the corresponding input key based on the sense result of the sensor from a memory to input the first character or the second character.

Still aspect of the invention is a data input device, comprising: a plurality of input keys in which a one-stage input for inputting a first character and a two-stage input for inputting a second character are independently performed; means for sensing the one-stage input and the two-stage input to the input keys; and means for extracting the first character or the second character redundantly assigned to the corresponding input key based on the sense result of the sensor from a memory to input the first character or the second character.

### BRIEF DESCRIPTION OF THE DRAWINGS

FIG. 1 is a front view of a mobile communication terminal in which a data input device according to an embodiment of the present invention is mounted.

FIG. 2 is a front view of a mobile communication terminal in which a data input device according to another embodiment of the present invention is mounted.

FIGS. 3 and 4 are side sectional views according to various embodiments of the present invention.

FIG. 5 is a plan view illustrating the arrangement of a sensor according to one embodiment of the present invention.

FIG. 6 illustrates the input of continuous phonemes through a skim input according to one embodiment of the present invention.

FIGS. 7 to 9 illustrate the skim input according to one embodiment of the present invention.

FIG. 10 is a front view of a mobile communication terminal in which a data input device according to another embodiment of the present invention.

FIGS. 11 to 13 are perspective view and a plan view of input keys according to various embodiments of the present invention.

FIGS. 14, 15, and 17 are plan views of a sensor according to various embodiments of the present invention.

FIG. 16 illustrates a combination input according to one embodiment of the present invention.

FIGS. 18 to 23 illustrate various arrangements of a first input key and a conversion input unit in the data input device according to one embodiment of the present invention.

FIGS. 24 and 25 illustrate a sequential input according to one embodiment of the present invention.

FIGS. 26 to 30 are perspective views of a first input key and a second input key according to various embodiments of the present invention.

FIG. 31 illustrates an event input according to one embodiment of the present invention.

FIG. 32 is a perspective view of a mobile communication terminal in which two data input devices are mounted.

FIGS. 33 and 34 illustrate an input example according to various embodiments of the present invention.

### DETAILED DESCRIPTION OF CERTAIN INVENTIVE EMBODIMENTS

Input devices of various characters or commands in the currently used information apparatuses have many problems so that the information apparatuses cannot properly correspond to the above-described changes in information environments.

That is, what is most important to an input of characters is to rapidly and correctly input information. Therefore, it is preferable that necessary characters be correctly input by the minimum number of operations.

In the above respect, a separate input key is to be set in every character to be input in an input device, which means that no less than 100 input keys including 24 Korean characters, 26 English characters, 10 numbers, and various signs are required.

In particular, it is limited to increase the number of input keys due to limitations on a space in a small information apparatus such as a mobile communication terminal or PDA. That is, in the case of a mobile communication terminal where 12 input keys of a 4×3 arrangement are provided, when the 24 Korean characters or the 26 English characters are arranged in the 12 input keys, two or three characters are redundantly assigned to one input key.

Therefore, in the above data input device, in order for a user to select a desired character, since input keys must be repeatedly operated, an input time is long and there is a high chance of generating erroneous typing and operations during complicated input processes so that input correctness deteriorates.

On the other hand, in order to solve the above-described problems, a Korean character input device of an electronic apparatus in which, after the consonants and vowels of Korean characters are arranged on a touch screen and a consonant is input by an initial touch, a drag is made on the touch screen to input a vowel, was proposed.

In this case, vowels are not displayed on the touch screen to simplify the screen. However, since the vowels are input by the drag, a drag path is not uniform in accordance with a user so that visibility deteriorates and that input correctness is low and the input path in accordance with the drag is long and complicated so that input time increases.

In addition, when the consonants and vowels are arranged on the touch screen, all of the necessary phonemes are arranged in a limited space so that the space assigned to each phoneme is too small and that it is not possible to correctly touch only a desired key with being interfered by another key while rapidly inputting the phonemes. Therefore, an input tool such as a stylus pen must be additionally provided. However, it is L not possible to rapidly input characters by the stylus pen.

In particular, in the case of inputting characters using the above-described touch screen, it is not possible to input the characters in a mobile telephone and a computer for which the touch screen is not used. Therefore, additional cost increases since the touch screen and a character recognition module must be provided.

Embodiments of the present invention will be described in detail with reference to the attached drawings.

### First Embodiment

A data input device according to a first embodiment of the present invention includes a plurality of input keys 10 in which a one-stage input for inputting a first character and a second stage input for inputting a second character are independently provided, a sensor 20 for sensing the one-stage input and the second stage input performed by the input keys 10, and a controller for extracting the first character or the second character redundantly assigned to the corresponding input keys 10 based on the sensing result of the sensor 20 to input the extracted the first character or the second character.

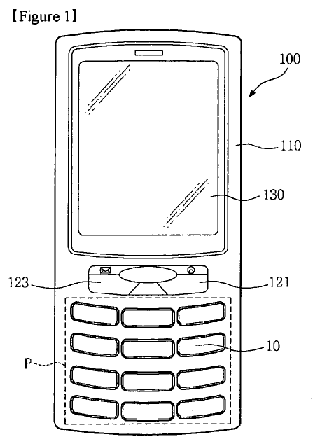

Referring to FIG. 1, a mobile communication terminal 100 includes a predetermined input region P and a case 110 in which a display 130 is provided.

The plurality of input keys 10 are provided in the input region P provided in the case 110. The display 130 on which the characters input by the input keys 10 are displayed is provided on one side of the case 110.

Here, as illustrated in FIG. 1, the input region P can be provided in the case 110 and can be provided in the display 130.

That is, an input method according to one embodiment of the present invention can be realized on a touch screen or a touch pad. In this case, a touch input is made so that data are displayed on a touch pad or a touch screen and a pressure sensor is further provided under the touch pad or the touch screen so that a pressure input can be performed.

The above-described can be commonly applied to all of the embodiments referred to hereinafter.

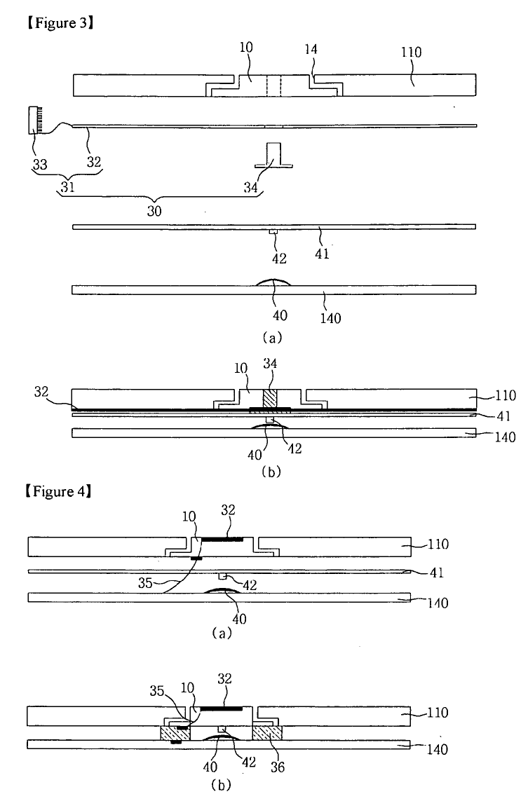

The input key 10 can have various shapes. For example, as illustrated in FIGS. 3 and 4, the input key 10 can be a cylinder, a polygonal cylinder, or a rectangle so that one region of the input key 10 is exposed to the outside through a through unit 14 provided in the case 110.

As illustrated in FIG. 3, the input keys 10 are separated from the case 110 so that the input keys 10 separately move. However, the input keys 10 are integrated with each other so that transformation can be performed by pressing the regions corresponding to the input keys 10.

The input key 10 is provided so that a one-stage input for inputting a first character and a two-stage input for inputting a second input are independently performed.

Here, the structures illustrated in FIGS. 3 and 4 are only an example for realizing the touch input and the pressure input.

Here, the one-stage input and the two-stage input can be variously provided. For example, the first stage input can be provided as the touch input in accordance with contact or approach to the input keys 10 and the two input can be provided as the pressure input so that the input keys 10 move up and down.

The one-stage input and the two-stage input can be provided as the pressure input distinguished by the magnitude of the up and down movement of the input keys 10 or the magnitude of pressure.

On the other hand, as illustrated in FIG. 34, a plurality of first input keys 11 arranged in a circle and provided so that the one-stage input for inputting the first character and the two-stage input for inputting the second character by pressure are independently performed and a second input key 12 provided inside or outside of the first input key 11 to input a seventh character by touch or pressure can be further included.

Hereinafter, the touch input and the pressure input will be described with reference to FIGS. 3 and 4.

In FIGS. 3 and 4, various embodiments of the input keys 10 using the touch input as the one-stage input and the pressure input as the two-stage input.

The touch input means inputting the first character assigned to the input key 10 by sensing the contact or approach to the input keys 10. Since the touch input is sensed by touch sensors 30, the touch sensors 30 are provided to correspond to the input keys 10 so that the touch sensors 30 sense that the fingers of a user contact the input keys 10 or approach the input keys 10 within a predetermined distance.

Various kinds of materials can be used as the touch sensors 30. For example, the touch sensors 30 can be formed of a non-contact sensor such as an optical sensor and a supersonic sensor and can be formed of a contact/non-contact sensor like electrostatic capacity sensors 31.

As illustrated in FIG. 3A, the electrostatic capacity sensor 31 includes a conductive contact member 32 that contacts the input key 10 and a measuring element 33 for measuring the electrostatic capacity of the contact member 32.

When the fingers of a user contact or approach the input keys 10, a change in electrostatic capacity is generated by the contact member 32.

Measuring elements 33 measure the change in the electrostatic capacity generated by the contact member to transmit the change in the electrostatic capacity to a controller. The controller determines that an effective signal is received when the change in the electrostatic capacity is no less than a predetermined magnitude to perform the touch input.

When the keys are contacted and pressed by the fingers of a user, the magnitude of the electrostatic capacity varies so that a multiple stage input can be performed.

Here, when the contact member 32 is not exposed to the upper surface of the input key 10, a contact body 34 for electrically connecting the contact member 32 and the upper end of the input key 10 to each other may be further provided. Here, FIG. 3B is a combination sectional view of FIG. 3A.

FIG. 4A illustrates the case in which the contact member 32 is provided in the upper end of the input key 10 and the measuring element 33 is provided on a printed circuit board (PCB) 140.

In this case, a connection line 35 for transmitting the electrostatic capacity generated by the contact member 32 to the measuring element 33 can be further provided between the contact member 32 and the measuring element 33.

When the input key 10 includes a conductive material, as illustrated in FIG. 4B, a conductive elastic member 36 provided between the input key 10 and the PCB 140 to transmit the electrostatic capacity generated by the contact member 32 to the measuring element 33 can be further provided.

Here, the conductive elastic member 36 performs the function of a return member of restoring the input key 10 to an initial position when the pressure input is performed as well as electrically connects the input key 10 and the PCB 140 to each other.

The touch sensors 30 can be arranged in the input region P by various methods. For example, one touch sensor 30 can be provided to each input key 10. As illustrated in FIG. 5A, the plurality of touch sensors 30 can be arranged in the entire input region P. As illustrated in FIG. 5B, the touch sensors 30 can be arranged in the input region to form lattices of the X and Y axes.

Two or more touch sensors 30 can be provided in each input key 10.

The pressure input means sensing the up and down movement of each input key 10 to input the first character or the second character assigned to the input key 10.

Therefore, pressure sensors 40 are provided to correspond the input keys 10 and to sense the up and down movements of the input keys by pressure.

The pressure sensors 40 can sense the movements of all of the input keys 10 and can sense the movements of parts of the input keys 10. In the latter case, for example, an electric element can be provided in the center of the input keys 10 and a pressure sensor for sensing pressure when the input keys 10 are pressed can be provided under the elastic member.

Various kinds of the pressure sensor 40 can be provided. For example, a pressing switch switched in accordance with the up and down movements of the input key 10 due to pressure or a pressure sensor for sensing the pressure applied to the input key 10 can be used as the pressure sensor 40,

When the pressure switch or the pressure contact sensor is used as the pressure sensor 40, as illustrated in FIG. 4B, a return member for restoring the input key 10 in which the pressure input is performed to an initial position can be further provided.

On the other hand, pressing plates 41 provided between the input keys 10 and the pressure sensors 40 to be connected to and separated from the pressure sensing units 40 in accordance with the movements of the input keys 10 can be further included.

On the other hand, multiple input of two or more stages can be performed by the pressure input in accordance with the up and down movement distance of the input key 10 or the magnitude of the pressure applied to the input key 10.

That is, when the pressure multiple stage input is performed in accordance with the pressure distance, two or more pressure sensors 40 are sequentially provided on the movement path of the input key 10 to be separated from each other to sense the movement degree of the input key 10.

Therefore, when the pressure is provided to have two-stages, since one input key 10 can perform three operations such as the touch input of one-stage, the pressure input of one-stage, and the pressure input of two-stages on one key input 10 so that three characters can be input by one key and that the input capacity of the input key 10 increases by three times.

In the case of the pressure input, it is possible to obtain the same effect by the pressure input of one-stage, the pressure input of two-stages, and the pressure input of three stages.

Here, when the pressure input is formed of the multiple stage input of two or more stages, a click unit that makes a user feel clicking is provided in one of multiple stages so that the user can determine whether the pressure input is the multiple stage input.

On the other hand, the multiple stage input can be applied to the case where the input key 10 is divided into a first input key 11, a second input key 12, and a third input key 13. In addition, the multiple stage input can be applied to a conversion input unit 55 and an internal input unit other than the input key 10.

On the other hand, the controller can selectively determine the touch input and the pressure input performed by the same input key 10 to perform input and can perform input on all of the signals.

In particular, in the case of the data input device according to the present invention, since the touch input is inevitably performed when the pressure input is performed, the controller must be able to select signals when a plurality of sense signals are received so that an input is performed as a user desires.

For example, as described above, in the case where only the pressure input is to be performed by a predetermined input key 10, although the touch and the pressure are simultaneously sensed by the touch sensor 30 and the pressure sensor 40 corresponding to one input key 10, the controller can extract an input command from a memory based on the result sensed by the pressure sensor 40 to execute the input command when a sense interval is within a predetermined time.

In the above case, to the contrary, only the touch input can be determined to be effective.

The controller extracts the input command caused by the touch input and the pressure input by various methods to execute the input command.

For example, when the touch input is cancelled with a predetermined delay time (contact maintaining time) after the touch input, the controller extracts the characters assigned to the touch input and the pressure input of the input key 10 from a memory to execute the command.

In the case where Korean consonants are input, when the touch input or the pressure input is continuously sensed twice within a predetermined time, doubled consonants can be input.

When the touch input or the pressure input is continuously sensed by no less than a predetermined time, doubled consonants can be input.

The input keys 10 can be variously arranged.

As illustrate in FIG. 1, the input keys 10 can be arranged in a rectangle formed of two or more rows and columns.

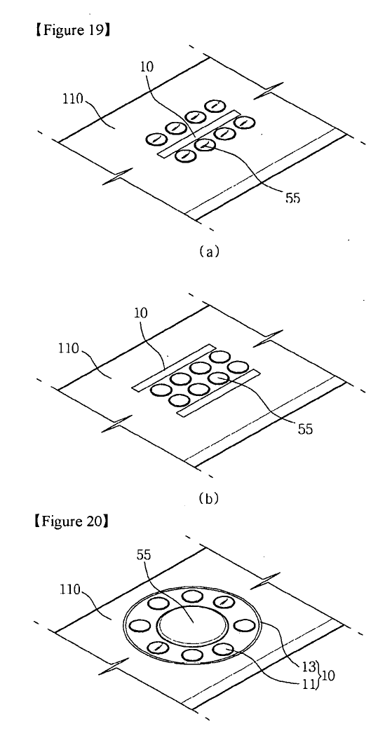

In this case, the number of input keys 10 can be 12 of 4×3, which is commonly used for the mobile communication terminal 100. As illustrated in FIG. 19, the number of input keys can be 8 of 4×2.

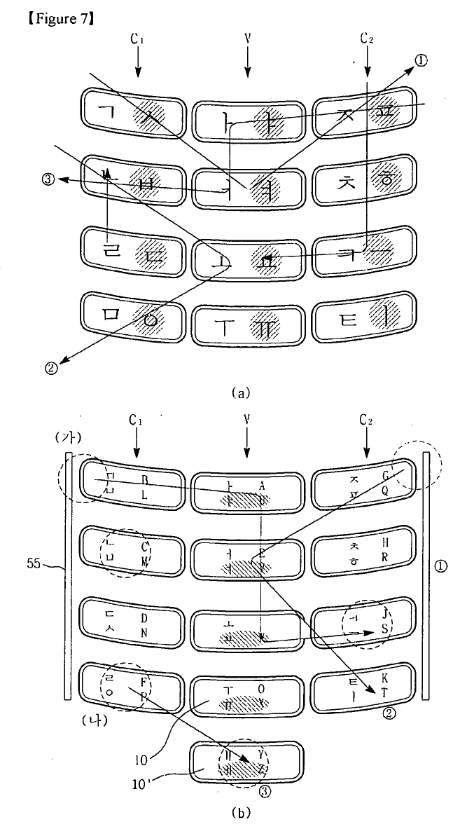

In the former case, as illustrated in FIG. 7B, one key can be added so that the thirteen input keys are provided.

When the number of input keys 10 is no less than 13, the 26 English characters are arranged in the input key 10 so that two characters are provided in each input key 10. Therefore, inputs are performed so that one input is the touch input (or the pressure input of one-stage) and that the other input is the pressure input (or the pressure input of two-stages).

In the case of inputting Korean characters, 24 Korean phonemes are redundantly provided in the 12 input keys 10 and the other input keys 10 to which the phonemes [symbol] and [symbol] are redundantly assigned can be further provided.

As illustrated in FIG. 7B, the conversion input unit 55 for converting a consonant into a vowel by performing the combination input by the input keys 10 so that the vowel is input can be further provided.

In the case where, when predetermined consonant and vowel are simultaneously assigned to the input keys 10, the consonant is input by the single input performed by the input key 10 and the consonant is converted into the vowel to be input by the combination input (simultaneously contacts the input keys 10 or contacts the input keys within a predetermined time (refer to FIG. 7A) performed by the conversion input unit 55.

The conversion input unit 55 can be provided in various positions. For example, the conversion input unit can be provided outside the input keys 10 as illustrated in FIG. 7B and can be provided inside the input keys 10 as illustrated in FIG. 19A.

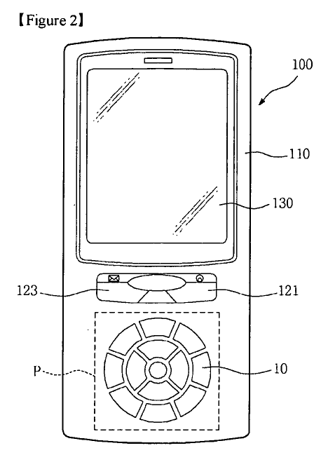

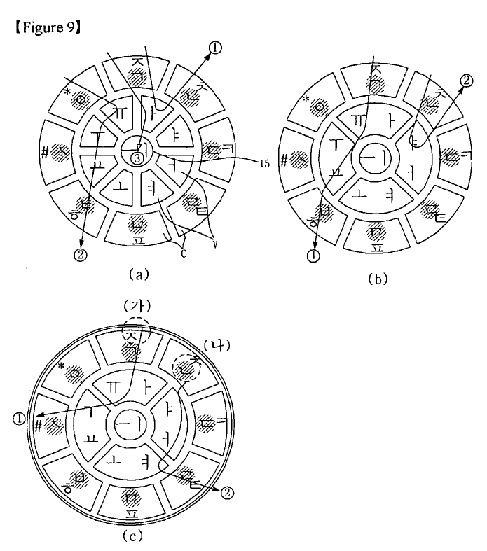

On the other hand, as illustrated in FIGS. 2 and 9, the input keys 10 can be radially arranged on the circumference of a circle having a predetermined radius. In this case, the input keys 10 can be separated from each other to be singly selected or can be connected to each other to be integrated.

When the input keys 10 are separated from each other, the input keys 10 can be provided in four radial directions or in eight radial directions. In this case, the input keys 10 can be separated from each other to be singly selected or can be connected to each other to be integrated with each other.

When the input keys 10 are separated from each other, the input keys 10 can be provided in the four radial directions or in the eight radial directions.

The input keys 10 can be provided in five, six, and seven radial directions.

When the input keys 10 are provided in two columns of the first input keys 11 and the second input keys 12 on a concentric circle, the number of first input keys 11 can be equal to or different from the number of the second input keys 12. For example, the number of first input keys 11 or second input keys 12 is 4 and the number of other keys is 8.

When the input keys 10 is integrated with other or is in the form of a separated ring, all of the input keys 10 can rotate. Therefore, scrolling, changing a mode, and various commands can be performed.

In addition, as illustrated in FIG. 2, the input keys 10 can be separated provided on concentric circles of two or more columns and can be arranged on one circle. Although the input keys 10 are arranged in a circle, as illustrated in FIG. 9C, the conversion input unit 55 can be provided.

On the other hand, two pairs of input keys 10 can be provided on both sides of the input region P. Hereinafter, the data input device according to all of the embodiments can be provided in two pairs as illustrated in FIG. 32. ‘Skim input’ used for the present specification means performing input while continuously touching or pressing the plurality of input keys 10.

For example, in the case of the Korean characters, the characters corresponding to an initial sound, a medial sound, and a final sound are not input by the independent input operations (that is, operations of separately pressing the input keys on a mobile communication terminal or a computer keyboard) but are input while skimming (or pressing) the input keys 10 in accordance with the paths on the input keys.

On the other hand, when the skim input in which at least one of the touch and the pressure is sequentially performed by three or more input keys 10 is performed, the controller selects some effective signals among the plurality of input signals.

For example, an input command is extracted from a memory based on the result obtained by sensing the initial input and the final input to execute the input command.

A signal can be determined as being effective only when a predetermined delay time (sense maintaining time) or a displacement amount is sensed. In the case where the skim input is curved in a direction that is not a linear direction when multiple input signals are generated, only the input signal generated in the bent point can be processed as being effective.

All of the terminals are connected to each other so that the data value of the point where a signal is generated and the data value of the point where the signal is cut off can be input.

Here, in the skim input, an input include the touch input, a mixture of the touch input and the pressure input, or the pressure input performed by the two or more input keys 10.

The first character and the second character are redundantly assigned to the input keys 10. The first character is assigned to be input by, the touch input (or the pressure input of one-stage when the pressure is input is used). The second character is assigned to be input by the pressure input (or the pressure input of two-stages).

Here, the first character and the second character can be provided without limitations. For example, the first character and the second character can be different kinds of characters such as a Korean character and an English character and can be divided into a consonant and a vowel.

For example, in the case of English characters, the vowels can be ‘A, E, I, O, and U’ and the consonants can be ‘W, X, and Y’. Here, various characters can be assigned to the input keys 10 such as numbers and signs as well as the above-described Korean and English characters.

On the other hand, on or two or more Korean and English characters can be redundantly arranged in the input keys 10. When the skim input can be performed, frequently used continuous consonants and continuous vowels may be arranged to be continuous to the adjacent input keys 10.

Here, the continuous phonemes including continuous constants or continuous vowels mean that frequently used words are continuously arranged and that two phonemes are continuously used in a word such as a consonant cluster in the Korean characters and ‘ch’ and ‘ng’ in the English characters.

For example, the continuous consonants are [symbol] [symbol] [symbol] in the case of the Korean characters and are ‘ch, ng, ing, gh, ght, . . . ’ in the case of the English characters. The continuous vowels are [symbol] [symbol] in the case of the Korean characters and are ‘ae, ea, au, yu, yo, ou, ex, . . . ’ in the case of the English characters.

The continuous consonants and vowels obtained by mixing the consonants and the vowels with each other are [symbol] [symbol] in the case of the Korean characters and ‘ed, er, on, ion, . . . ’ in the English characters .

In the above-described case, in the case of ‘ght’ and ‘ion’, the three characters are continuously assigned to the adjacent input keys and the three input keys 10 are skimmed so that three phonemes are input by making the skim input once.

In this case, the three or more input signals sequentially generated by the skim input are determined to be effective by the controller to be input.

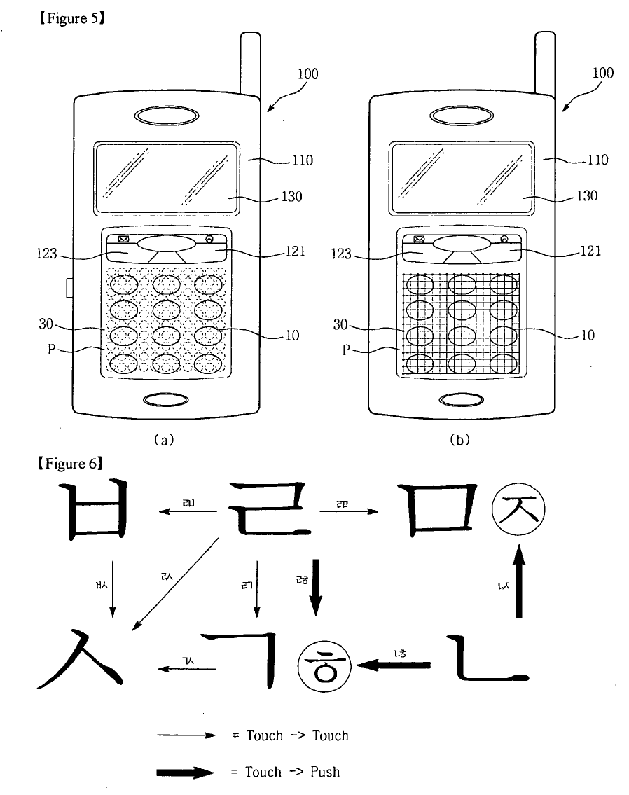

FIG. 6 illustrates an input of continuous phonemes through a skim input according to another embodiment of the present invention.

In FIG. 6, thin arrows denote the skim input of inputting characters only by the touch input and thick arrows denote the mixture of the touch input and the pressure input. That is, when [symbol] is to be input, after touching [symbol] is immediately touched. When [symbol] is to be input, after touching [symbol] is immediately pressed.

The plurality of input keys 10 can be divided into consonant input key sets C to which the consonants are assigned and vowel input key sets V to which vowels are assigned to be arranged.

‘The consonant input key sets C’ and ‘the vowel input key sets V’ according to one embodiment of the present invention mean the sets of the plurality of input keys 10 to which the consonants and the vowels are assigned.

In the same input key sets, the same characters are assigned and arranged. However, the input keys 10 are divided into the input key sets when the Korean characters, the English characters, and Japanese characters are input for convenience sake in accordance with the kinds of the assigned characters.

Such a division does not have any additional meaning when the signs and the numbers are arranged and input.

On the other hand, when the input keys 10 are divided into the consonant input key sets C and the vowel input key sets V, the consonant input key sets C and the vowel input key sets V can be arranged so that the input keys 10 are sequentially touched in the order of a consonant and a vowel or of a consonant, a vowel, and a consonant.

The consonant input key sets C and the vowel input key sets V can be arranged so that the input keys 10 are sequentially touched in the order of a consonant, a consonant, and a vowel or of a vowel, a consonant, and a consonant during the skim input.

Hereinafter, the specific input example of the data input device according to one embodiment of the present invention will be described with reference to FIGS. 7 to 9. First, referring to FIG. 7A, in the input keys 10 of 4×3, the consonant input key sets C are divided into a first consonant input key set C1 of one column and a second consonant input key set C2 of three columns and the vowel input key sets V are provided in a second column.

Two characters are redundantly assigned to the input keys 10 included in the consonant input key sets C and the vowel input key sets V. Therefore, the characters positioned on the input keys 10 are input by the touch input and the characters (blackened parts) positioned under the input keys 10 are input by the pressure input. Therefore, when a user performs the skim input only by the touch input through a first path \textcircled{1}, [symbol] are sequentially input so that [symbol] is input.

When the pressure input is performed by the first consonant input key set C1 and then, the touch input is performed on the same path, [symbol] is input.

When [symbol] is to be input, the touch input, the touch input, and the pressure input are continuously performed along a second path \textcircled{2}.

When the pressure input, the touch input, and the touch input are continuously performed on the same path, [symbol] is input. That is, in the data input device according to the present invention, the input keys 10 are divided into the vowel input key sets V and the consonant input key sets C and the vowel input key sets V are provided between the consonant input key sets C.

Therefore, the character composed of consonants and a vowel can be effectively input through continuous operations during an input of the character.

In addition, continuously and frequently used consonant and vowel, for example, [symbol] and [symbol] or [symbol] and [symbol] are arranged to be adjacent to each other so that the character can be input through the shortest path.

Therefore, it is possible to minimize input time and to correctly input the character. For example, [symbol] or [symbol] that is frequently used during an input of the Korean characters, the touch input and the touch input are performed along the fifth path \textcircled{5} of FIG. 7 and the touch input and the pressure input are performed along the sixth path \textcircled{6} so that the continuous consonants can be input.

In one embodiment, in the data input device, since the vowel input key sets V and the consonant input key sets C are effectively arranged and the continuous consonant and the continuous vowel in the input key sets V and C are arranged to be adjacent to each other, it is possible to effectively input the character.

On the other hand, in FIG. 7A, when the skim input is performed, two or more touches or pressures can be continuously performed in the same input key sets C and V like the third path \textcircled{3} or the fourth path \textcircled{4} if necessary.

In this case, the controller determines that only some of the sense results are effective to extract a character from the memory and to input the extracted character.

For example, the controller can determine that only one of the initial sense signal or the final sense signal is effective among the plurality of sense results. That is, on the third path \textcircled{3}, when the controller determines that only the initial sense signal is effective in the vowel input key sets V, an input of [symbol] is ignored.

Therefore, when the skim input is performed only by the touch, [symbol] is input. To the contrary, when the controller determines that only the final sense signal is effective, [symbol] is input.

On the fourth path \textcircled{4}, [symbol] is input when the initial sense signal is selected and the skim input is performed only by the touch input and [symbol] is input when the final sense signal is selected.

Here, in a method of determining the final sense signal, for example, in the case where a plurality of sense signals are continuously generated, when the generation of a signal is stopped at one point of time, the signal is determined as the final sense signal.

In the case where two or more skim inputs are continuously sensed at a predetermined interval and no next sense signal is generated after a predetermined sense signal for no less than a predetermined time, the signal can be determined as the final sense signal.

Other than the above-described example, the controller can determine the initial input and the final input or the touch input or the pressure input performed by the input key 10 at the bent point (for example, the input key 10 to which [symbol] is assigned on the fourth path \textcircled{4}) to be effective in the skim input performed by the input key 10 in the same input key sets C and V.

The controller can determine only the signals maintained for no less than predetermined input time to be effective among the plurality of sense results input by the same input key sets C and V. That is, when a finger stays on the input key 10 to which [symbol] is assigned for no less than a set time (for example, one second) in order to input [symbol] on the fourth path \textcircled{4}, [symbol] or [symbol] is ignored so that [symbol] is input.

In general, the sense signal is maintained for no less than predetermined input time when an input starts (the position on which a finger first stays), when an input is terminated (the position from which a finger is lifted), or when an input state is maintained (the position on which a finger stays for no less than input time).

Therefore, only the characters desired to be input can be easily input through an operation of continuously commanding the characters to be input without additional learning.

Here, a difference in the input time is very small. However, the difference can be distinguished by setting time to distinguish a valid input from a void input. An input process by setting input time (referred to as setting delay time) is used for various electronic products and the scroll function of the touch pad.

On the other, in the case where the touch sensor 30 is formed of an electrostatic capacity sensor, an input signal is determined to be effective only when a change in electrostatic capacity in accordance with the degree of contact (an area or strength) is no less than a set value.

On the other, in the case of an input of a doubled consonant, the touch input or the pressure input is continuously performed twice within predetermined input time on an input key 10 to which a corresponding consonant is assigned, the touch input or the pressure input is performed for no less than predetermined delay time, or the touch input or the pressure input is performed while an input is performed by an additional functional key (not shown).

Referring to FIG. 7B, like in FIG. 7A, in the input keys 10 of 4×3, the consonant input key sets C are divided into the first consonant input key set C1 of one column and the second consonant input key set C2 of three columns, the vowel input key sets V are provided in the second column, and the conversion input unit 55 separated from the input keys 10 by a predetermined distance is provided on the left side of the first column and on the right side of the third column.

When the conversion input unit 55 is selected to the input key 10 included in the consonant input key sets C, an input signal different from the signal assigned to the input key 10 is input.

When an input of a Korean consonant is described as an example, the consonant [symbol] or ‘B’ provided in the upper side of each input key 10 is input by simultaneously touching the conversion input unit 55 and the input key 10 as illustrated in [symbol] and the consonant [symbol] or [symbol] provided in the lower side of the input key 10 is input by touching the input key as illustrated in [symbol] .

Here, in the case of the vowel input key sets V, like in the above-described embodiment, the characters provided in the upper side is input by the touch input and the characters (blackened parts) provided in the lower side are input by the pressure input.

An example of inputting an English word ‘BUS’ through the first path \textcircled{1} will be described. First, in order to input ‘B’ as illustrated in [symbol] the conversion input unit 55 and the input key 10 are simultaneously touched. Then, movement is made to the input key 10 to which ‘U’ is assigned. Then, movement is made to the input key 10 to which ‘S’ is assigned. At this time, only the input key 10 is touched so that the conversion input unit 55 is not selected.

Here, only the initial signal is determined to be effective among the plurality of sense signals in the vowel input key sets V as described above.

The second path \textcircled{2} is for describing the input of an English word ‘GET’. When ‘G’ is input, the conversion input unit 55 and the input key 10 must be touched. However, when ‘T’ is input, only the input key 10 must be touched.

On the other, the vowel input key sets V can include 5 input keys 10 unlike the consonant input key sets C arranged in a first column and a third column. [symbol] or [symbol] can be provided in an added input key 10′ in the case of the Korean characters.

In the case of the English characters, 26 characters can be redundantly arranged in the 13 input keys 10 by two. Therefore, when the touch input and the skim input are performed along the third path \textcircled{3} of FIG. 7B, [symbol] is input. When the touch input and the pressure input are performed [symbol] is input.

Here, the conversion input unit 55 can have various kinds. For example, the conversion input unit 55 can be a touch type conductive terminal or a ring-shaped pressure button.

On the other hand, the conversion input unit 55 can perform other functions than consonant conversion in other modes than a character input mode. For example, when movement is made from side to side while the conversion input unit 55 is maintained to be touched, a volume controlling or scrolling function can be performed.

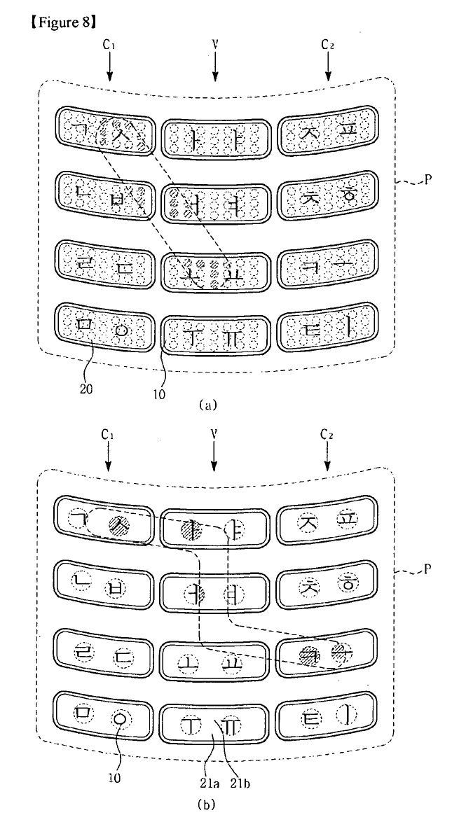

On the other hand, as illustrated in FIG. 8A, the plurality of touch sensors 30 are arranged in the entire input region P or in the input keys 10 so that the controller determines that the selection of the input key 10 to be valid only when touch is sensed in the touch sensors 30 of no less than a set number among the plurality of touch sensors 30 arranged in the input keys 10 during the performing of the skim input.

In the data input device 1, when the skim input is performed, in the case where movement is made while skimming two or more input keys 10 by which characters are input along the shortest path, an undesired input key 10 can be touched.

For example, in FIG. 8A, when a user wishes to input [symbol] the input key 10 to which [symbol] is assigned is first touched and then, movement is to be made to the input key 10 to which [symbol] is assigned and that is positioned in a diagonal direction while performing skimming.

At this time, the area touched while a finger is moved is displayed by dot lines as illustrated in FIG. 8A. In this case, when it is determined that all of the results sensed by the touch sensors 30 assigned to the input keys 10 are effective, undesired characters, that is, [symbol] or [symbol] can be input.

However, since other input keys 10 such as [symbol] and [symbol] than the input keys 10, that is, [symbol] and [symbol] to which characters to be input are simply hung on the shortest path, the touch area of the other keys is smaller than the touch area of the selected input keys 10.

Therefore, as illustrated in FIG. 8A, the plurality of touch sensors 30 are arranged (dot lined circles) in the entire input region P or on the input keys 10 so that the sense result is determined to be effective only when the number of touch sensors 21 (blackened dot lines) sensed to be doubly touched is no less than a set number, for example, 10.

Therefore, interference between the input keys 10 is prevented during the skim input so that the characters desired by a user are correctly input. Therefore, the user can correctly perform a desired input in the case where two or more input keys 10 are simultaneously selected when the plurality of input keys 10 are densely arranged in the narrow input region P.

Although movement is simultaneously sensed in two or more input keys 10, it is automatically determined to which input key 10 a finger is closer (or which input key 10 a finger touches more). Since a plurality of sensors 20 exist, it can be determined whether the sensor 20 corresponding to which input key 10 is more sensed or whether in which input key 10 the center of the a contact area is included.

The interference prevention using the plurality of sensors 20 can be applied regardless of the interference between all of the input keys 10 used according to one embodiment of the present invention, for example, a first input key 11, a second input key 12, a third input key 13, the conversion input unit 55, and an internal input key 15. The kinds of the sensor 30 are not limited.

The two or more touch sensors 30 are provided in the input keys 10 to be separated from each other by a predetermined distance. The controller can determine that the selection of the input key 10 is effective only when touch is sensed by the two or more touch sensors 30. That is, referring to FIG. 8B, the two touch sensors 30 are provided on the input keys 10 to be separated from each other up and down or side to side.

The controller can determine that the selection of the input key 10 is effective only when touch is sensed by all of the touch sensors 30 provided on the input keys 10. Therefore, when the skim input is performed by making touch along the path displayed by dot lines in FIG. 8B, since [symbol] cannot be sensed by the two touch sensors 30, [symbol] is not an effective signal. Therefore, [symbol] is input.

On the other hand, in the data input device 1 according to one embodiment of the present invention that is illustrated in FIG. 9, the consonant input key sets C and the vowel input key sets V are provided to be circular on two concentric circles having different diameters.

On the other hand, the vowel input key sets V can be provided on an internal column and the consonant input key sets C can be provided on an external column. To the contrary, the vowel input key sets V can be provided on the external column and the consonant input key sets C can be provided on the internal column.

When the consonant input key sets C are provided outside, in the case where the touch input and the pressure input can be separately performed on the input keys 10 included in the consonant input key sets C, as illustrated in FIGS. 9A and 9B, the 8 consonant input key sets C can be provided. In the case where only the touch input can be performed, as illustrated in FIG. 9C, a conversion input unit 40 can be further provided outside the consonant input key sets C.

On the other hand, when only the touch input can be performed, as illustrated in FIG. 9A, the number of vowel input key sets V can be 8. When the touch input and the pressure input can be separately performed, as illustrated in FIGS. 9B and 9C, the number of vowel input key sets V can be 4.

Here, when the vowel input key sets V are integrated, the vowel input key sets V can perform other functions in other modes than a character input mode. For example, the vowel input key sets V can perform a direction indicating function such as a mouse function, a mode selection function, confirmation/cancel functions, and a volume controlling or scrolling function.

On the other hand, as illustrated in FIGS. 9A to 9C, an internal input key 15 having one or more functions between the touch input and the pressure input can be provided in the vowel input key sets V.

The consonants or the vowels can be provided in the internal input key 15. Commands such as a character conversion, an input mode conversion, and confirmation/cancel can be assigned to the internal input key 15. calling/ending functions can be assigned to the internal input key 15 during a communication mode.

On the other hand, the pressure input of the internal input key 15 can be divided into a one-stage pressure input and a two-stage pressure input in accordance with the strength of pressure.

In the above-described cases, since the determining of a valid signal among a plurality of sensed signals in the input key sets C and V and the preventing of interference between the input keys 10 were described in FIG. 8. Description thereof will be omitted.

Referring to the drawing, a detailed input example in the data input device 1 according to one embodiment of the present invention will be described as follows. First, referring to FIG. 9A, when touch, touch, and pressure are continuously input through the first path \textcircled{1}, [symbol] can be input and, when pressure, touch , and pressure are continuously input, [symbol] can be input.

In addition, in the case of the second path \textcircled{2}, when pressure, touch (when the initial signal is selected), and pressure are continuously input, [symbol] can be input. When pressure, touch (when the final signal is selected), and pressure are continuously input, [symbol] can be input. When touch, touch (maintained for no less than predetermined time), and pressure are continuously input, [symbol] can be input.

In the case of the third path \textcircled{3}, touch, touch (when the initial signal is selected), and pressure are continuously input to input [symbol] . When the internal input key 15 is used, touch, touch, and pressure (the internal input key 15) are performed to input

[symbol]

In the above-described case, when the pressure input is generated by the vowel input key sets V, the touch input in the previous or sequential vowel input key sets V are ignored to select the initial signal or the final signal.

On the other hand, in the case of the first path \textcircled{1} of FIG. 9B, touch [symbol] pressure [symbol] when the initial signal selected), and pressure [symbol] are performed to input [symbol] and touch, pressure (when the final signal is selected), and pressure are performed to input [symbol] In the case of the second path \textcircled{2}, touch [symbol] pressure [symbol] and pressure [symbol] are performed to input

[symbol]

On the other hand, referring to FIG. 9C, the conversion input unit 40 is provided outside the consonant input key sets C so that, when the input key 10 is singly touched (refer to [symbol] the characters (blackened parts) arranged inside are input.

When the input key 10 and the conversion input unit 40 are simultaneously touched (refer to [symbol] the characters arranged outside are input. That is, in the case of the first path \textcircled{1}, simultaneous touch [symbol] pressure [symbol] and pressure [symbol] are performed to input

[symbol]

In the case of the second path \textcircled{2}, simultaneous touch [symbol] pressure [symbol] when the final signal is selected), and single touch [symbol] are performed to input [symbol] and single touch [symbol] pressure [symbol] when the final signal is selected), and single touch [symbol] are performed to input

[symbol]

Therefore, in the data input device according to one embodiment of the present invention, the consonant input key sets C and the vowel input key sets V are circularly arranged on different concentric circles so that a consonant and a vowel or a consonant, a vowel, and a consonant can be continuously input through the shortest path.

Therefore, character input speed is minimized, an input can be correctly performed, and the external appearance of the input device is improved due to circular arrangement.

Here, the number of input keys 10 included in the input key sets C and V can vary. For example, the number of input keys 10 can be 8, no less than 9, and no more than 7.

In addition, the consonant input key sets C and the vowel input key sets V can have the same number and can have different numbers. In addition, different kinds of characters can be included in the input key sets in accordance with the numbers and the kinds of characters of the respective countries.

For example, when the Korean characters are arranged in the consonant input key sets C and the vowel input key sets V, since the number of Korean consonants is 14 and the number of Korean vowels is 10, the vowels [symbol] [symbol] and [symbol] are arranged in the 4 input keys 10 included in the vowel input key sets C and the vowels [symbol] and [symbol] can be arranged in the consonant input key sets V.

Here, the arrangement of the input keys provided in the present specification and drawing is only limited in that the vowel input key sets are provided between the consonant input key sets. However, the arrangement of the consonant characters or the vowel characters of the input keys included in the input key sets can vary without limitation.

On the other hand, various functional keys other than the above-described input key 10 can be further provided in the case 110. For example, a touch function selection key 121 for selecting the operation and the stopping of the touch sensors 30 may be further provided so that the touch input can be selectively performed.

A mode conversion key 123 for selecting a character input mode for inputting characters through the input keys 10 is further included. The touch sensors 30 operate when the mode conversion key 123 is selected to sense the touch input.

Here, the above-described touch function selection key 121 and the mode conversion keys 123 prevent an undesired input key from being contacted so that the touch input is performed when another common function is performed by an electronic apparatus such as a mobile telephone. That is, during a telephone call, a user supports both sides of the case 110 or the input region of the case 110 contacts or approaches the face of the user. In this case, the touch input can be performed regardless of the intention of the user.

In the above case, a number input can be performed by the pressure input and the touch input.

On the other hand, as described above, the input key 10 can perform a mode converting function, a menu selecting function, a volume controlling function, a cursor moving function, a direction indicating function, or a scrolling function as well as a data inputting function. The scrolling function is provided in a mouse so that signals continue.

The above function can be performed through sensed signals from side to side or up and down. When the input keys 10 are radially arranged, the above function can be performed through a signal in an arc direction of the input key 10.

On the other hand, another example of the present embodiment is illustrated in FIG. 34. Referring to FIG. 34, a plurality of radial second input keys 12 are provided outside a ring-shaped first input key 11. The internal input key 15 is further provided in the first input key 11.

Therefore, a one-stage input by touch and a two state input by pressure are performed by the first input key 11 and a one-stage input is performed by the second input keys 12 by touch or pressure.

In order to input the word ‘BUS’ in the corresponding structure, touch starts in the first input key 11 to which ‘B’ is assigned to input ‘U’ while proceeding from the internal input key 15 to the second input keys 12. Then, skimming is continuously performed to proceed to the first input key 11 where ‘S’ is positioned.

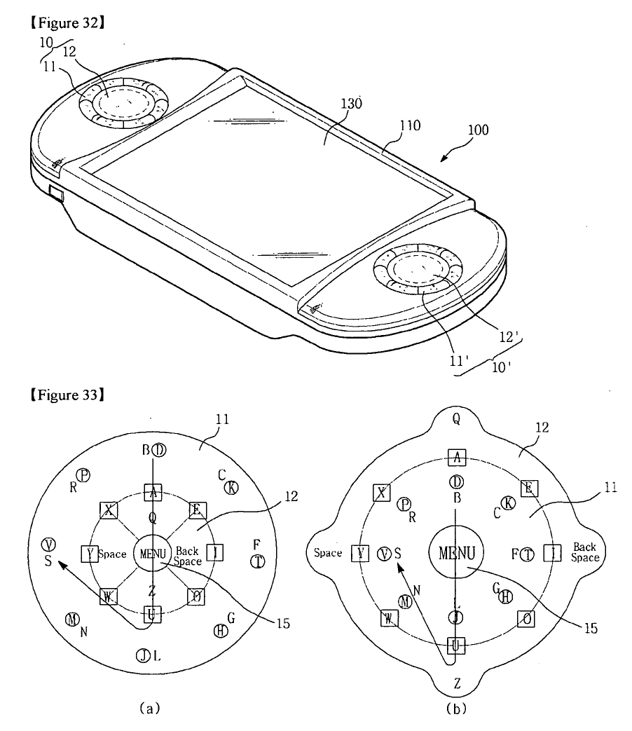

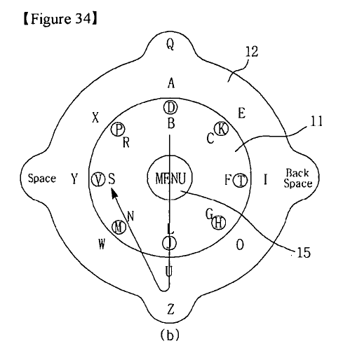

During the skim input as described above, the selection of an effective signal is illustrated in FIG. 33. When the skimming is performed, signals that are not cancelled or maintained are ignored. Therefore, only desired characters can be input without lifting a finger so that a rapid skim input can be performed.

Description of the one-stage and two-stage input structure in the input key 10, the touch input and the pressure input, the sensing method, the controlling method of the controller, the skim input, and two pairs according to the first embodiment is applied to at least one embodiment of the data input device.

Hereinafter, the above description is commonly applied when there are no additional comments in the embodiments.

### Second Embodiment

In the data input device according to the second embodiment of the present invention, the input keys 10 include the first input key 11 and the second input keys 12 provided to be adjacent to the inside or the outside of the first input key 11.

When a combination input in which the first input key 11 and the second input keys 12 are simultaneously selected within predetermined time is performed, the controller extracts a third character different from the character assigned to the corresponding input key 10 from a memory to input the third character.

As illustrated in FIG. 10, the input key 10 according to one embodiment of the present invention includes the first input keys 11 and the second input key 12 provided inside or outside the first input keys 11.

The first input keys 11 can be arranged in the form of a circle and a rectangle as described in the first embodiment. The number of first input keys 11 is not limited. When the first input keys 11 are arranged in the form of a circle as illustrated in FIG. 10, the second input key 12 can be provided inside or outside the first input keys 11.

On the other hand, data including various kinds of characters, numbers, and signs can be applied to the first input keys 1 and the second input key 12. In addition, when the characters are assigned, the first input keys 11 can be arranged in various methods. For example, consonants are input to the first input keys 11 or the second input key 12 and vowels can be input by the combination input.

On the other hand, as illustrated in FIG. 10, the first input keys 11 and the second input key 12 can be separated from each other, however, can have uniform regions, respectively, on a touch pad or a touch screen.

The first input keys 11 include a one-stage input for inputting a first character and a two-stage input for inputting a second character like in the first embodiment. The one-stage input and the two-stage input are provided for the touch input and the pressure input or a one-stage pressure input and a two-stage pressure input.

Here, the first character, the second character, and third to seventh characters input by the input keys 10 using a combination input or a sequential input vary. For example, the first character and the second character are consonants and the third to seventh characters are vowels.

In addition, in the above case, the pressure input can be a multiple stage input of two or more.

In the case of the touch input, a non-contact sensor such as an optical sensor, an ultrasonic sensor, and a non-contact electrostatic capacity sensor or a contact sensor such as a contact electrostatic capacity sensor can be used as the touch sensors 30. The sense method used for the touch pad or the touch screen under the first input keys 11 or the second input key 12 can be applied.

In the pressure input, a pressure switch switched by the pressure of a user or a pressure sensor for sensing the pressure applied by the pressure of the user can be used for the pressure sensor 40.

A return member for restoring the first input keys 11 to an initial position after the pressure input is performed can be further provided.

When the touch input and the pressure input are performed by the first input keys 11, since the touch input is sensed whenever the pressure input is generated, when the touch input and the pressure input are sensed within predetermined time, the controller ignores a signal generated by the touch input to process only a signal generated by the pressure input.

When only the pressure input of a multiple stage are performed by the first input keys 11, the multiple stage pressure input is determined by the movement distance of the first input keys 11 and the strength of the pressure. At this time, in order to make the one-stage pressure input different from the two-stage pressure input, a clicking unit such as a metal dome can be further provided.

In addition, a signal selection method between the touch input and the pressure input can be used as the effective signal selection between the one-stage pressure input and the two-stage pressure input.

In the data input device according to the second embodiment of the present invention, when the one-stage input or the two-stage input of the first input keys 11 is combined with the second input key 12, a third character is input.

Here, in the combination input between the first input key 11 and the second input key 12, for example, when an input is performed through a method of simultaneously selecting the first input key 11 and the second input key 12 within predetermined time, the controller considers the input as a new input signal so that another new character different from the character assigned to the first input key 11 is input.

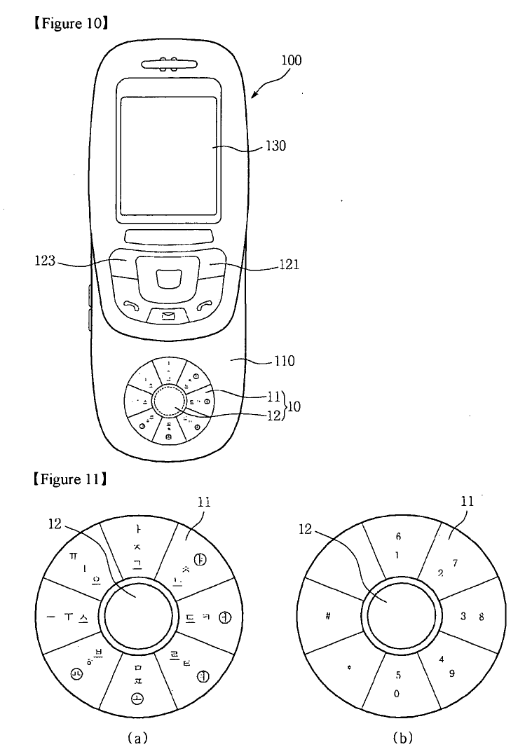

FIG. 11 illustrates the arrangement of the characters of the data input device according to one embodiment of the present invention. FIG. 11A illustrates an example of an input of Korean characters. FIG. 11B illustrates an example of the arrangement of numbers.

In the drawings, the underlined characters represent first characters input by a one-stage input, the characters that are not underlined represent the second characters input by a two-stage input, and the characters in circles represent third characters input by the combination input between the first input keys 11 and the second input key 12.

The plurality of second input keys 12 can be provided so that characters can be assigned to the second input keys 12. At this time, as illustrated in FIG. 16, the first characters and the second characters are displayed on the first input keys 11, the characters assigned to the second input keys 12 are displayed in the second input keys 12, and the third characters are displayed on the boundaries between the first input keys 11 and the second input keys 12 so that a user can easily input data.

As illustrated in the drawing, when the input data are the Korean characters, consonants are assigned to the first characters and the second characters or the characters generated by the single input of the second input keys 12 and the vowels can be assigned to the third characters. In this case, several consonants or vowels can cross other input keys 10 in accordance with the input capacity of the input keys 10.

FIG. 11 illustrates the case in which the arranged characters have three columns. In the above-described case, the first characters and the second characters input through the first input keys 11 may be consonants and the third characters input by the combination input between the first input keys 11 and the second input keys 12 may be vowels.

On the other hand, in order to input doubled consonants, additional doubled consonant input keys (not shown) are further provided. Therefore, the doubled consonants can be input by combining the doubled consonant input keys and the first input keys 11 or the second input keys 12. The input of the first input keys 11 is continuously performed twice to input the doubled consonants.

In the data input device according to one embodiment of the present invention, a plurality of sensors 20 for sensing the signal of the first input key 11 or the second input key 12 can be provided in each input key 10 for a correct input.

In the data input device according to the present embodiment, since the single input of the first input key 11 and the combination input between the first input key 11 and the second input key 12 is distinguished from each other, when the selection of the second input key 12 is sensitively sensed, during the signal input of the first input key 11, there is a high chance of generating input error.

Therefore, the sensor 20 for sensing the selection of the second input key 12 is composed of a plurality of sense lines so that the signal is determined to be effective only when the signal is sensed by sense lines of no less than a specific number.

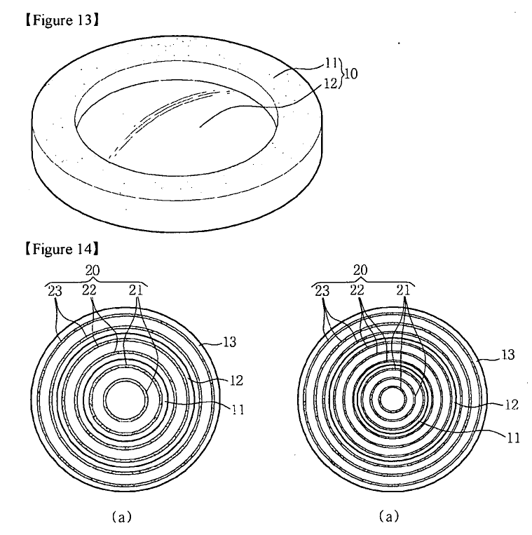

FIG. 14 illustrates an example in which each of a first input key sensor 21, a second input key sensor 22, and a third input key sensor includes a plurality of sense lines. FIG. 14A illustrates an example in which each of the first input key sensor 21, the second input key sensor 22, and the third input key sensor has two sense lines. FIG. 14B illustrates an example in which each of the first input key sensor 21, the second input key sensor 22, and the third input key sensor includes three sense lines.

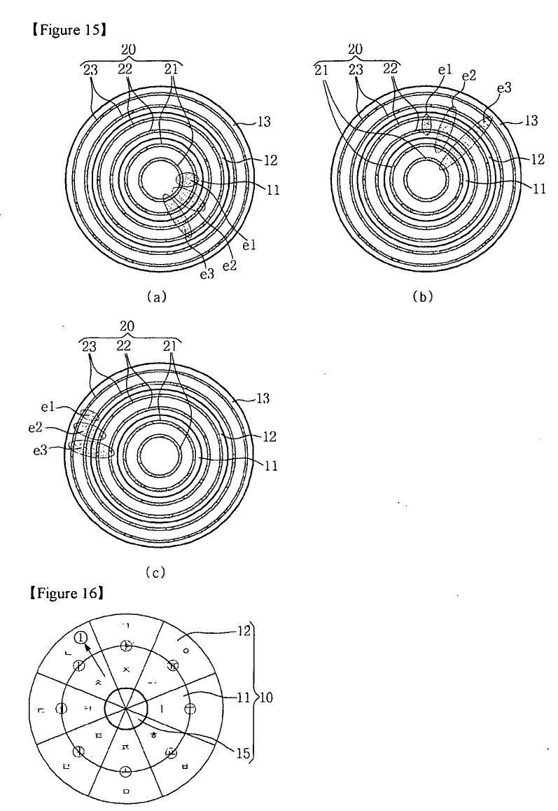

The number of sense lines can vary in accordance with conditions. FIG. 15 illustrates an input of a data input device according to a second embodiment of the present invention. FIG. 15A illustrates the signal processing of the first input key 11. FIG. 15B illustrates the signal processing of the second input key 12. FIG. 15C illustrates the signal processing of the third input key.

First, the signal processing of the first input key 11 is described with reference to FIG. 15A. When the signal of the first input key 11 is singly sensed (refer to e1) by the first key sensor 21, the data singly assigned to the first input key 11 is input.

When parts of the sense lines of the first input key sensor 21 and the second input key sensor 22 are simultaneously sensed (refer to e2), the controller determines only the signal of the first input key sensor 21 that is correctly sensed to be effective so that the same data as the data when the first input key sensor 21 is singly sensed is input.

According to another method of preventing the input error, the controller can determine that only the case in which time at which the sense signal of the first input key 11 is generated and time at which the sense signal of the second input key 12 is generated are within a predetermined interval is effective.

Although the controller ignores the signal of the second input key 12 in the case where the second input key 12 is skimmed so that the signals of the first input key 11 and the second input key 12 are sensed within predetermined time, the data input device according to one embodiment of the present invention can prevent an erroneous input from being generated by skimming so that an input can be continuously performed without lifting a finger from the input key 10.

That is, during the skim input of the characters, at the point where a movement path is bent, a finger stays longer than when the finger linearly skims the sense part. Therefore, since the signal sensed at the corresponding point becomes longer, only the signal input for no less than predetermined time can be determined as an effective signal.

In general, a difference between the skim input and signal maintaining time is generated in the position (the position where a finger first touches) where an input starts, the position (the position where a finger is finally lifted) where an input is terminated, and the position where an input is maintained. The difference in time is ignorable. However, an effective signal and an ignored signal can be processed by setting time.

Therefore, the user can input the characters to be input using the skim input by the movement of a finger without learning.

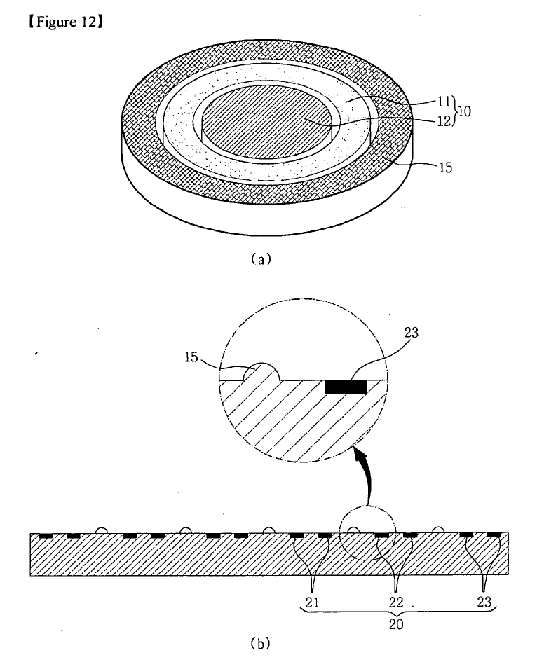

Through input processing (referred to as delay time) performed by setting input time, the scroll function of various electronic products or a touch pad is performed. The electrostatic capacity sensor is used as the touch sensors 30 so that a difference in displacement and a difference in input time can be used together. As illustrated in FIG. 13, the second input key 12 is provided to be semispherical so that the edge of the second input key 12 is positioned the boundary between the first input key 11 and the second input key 12 and that the second input key 12 is selected only when input is intentionally performed by the second input key 12.

The controller determines only the signal maintained for no less than predetermined time to be effective among the sense signals of the first input keys 11 and the second input keys 12 that are sensed by the sensors 20 to perform an input.

FIG. 10 is a use example in which the data input device according to one embodiment of the present invention is included. The data input device can be included in a mobile telephone that is made thin and small and to which data are to be rapidly input.

Furthermore, the data input device according to one embodiment of the present invention can be applied to various information apparatuses to which data are to be input as well as a mobile telephone.

On the other hand, as illustrated in FIG. 12A, a data input device according to a second embodiment of the present invention includes a first input key 11, second input keys 12 radially formed outside the first input key 11, and third input keys 13 radially formed outside the second input keys 12.

FIG. 12A illustrates that the first input key 11 is formed to be circular and the second input keys 12 and the third input keys 13 are sequentially formed outside the first input key 11 to be integrated in the form of a ring. However, the input keys including the first input key 11 can be formed by dividing a plurality of input keys. FIG. 12B is a sectional view of the data input device illustrated in FIG. 12.

Protrusions are formed on the boundaries among the first input key 11, the second input keys 12, and the third input keys 13 so that a user distinguishes the input keys from each other without looking at the input keys to easily grasp the positions of the input keys.

FIG. 16 illustrates an example in which a first character and a second character that are originally assigned to the input keys 10 are input by the single input of the first input key 11 and the second input key 12 and a third character is input by the combination input of the first input key 11 and the second input key 12.

Referring to FIG. 16, the number of first input keys 11 is 8 so that the first input keys 11 are radially arranged in an internal circle and the number of second input keys 12 is 8 so that the second input keys 12 are radially arranged outside the first input keys 11.

Assigned consonants are displayed on the first input keys 11 and the second input keys 12. The vowels displayed over the first input keys 11 and the second input keys 12 illustrate the third character input by the combination input of the first input key 11 and the second input key 12.

Therefore, as illustrated in FIG. 16, when the Korean consonants and the Korean vowels are arranged, consonant, vowel, and consonant can be input once by performing the skim input from the first input key 11 to the second input key 12. That is, when the skim input is performed along the path of \textcircled{1}, [symbol] (the single input of the first input key), [symbol] (the combination input of the first input key 11 and the second input key 12), and [symbol] (the single input of the second input key 12) are sequentially input to input [symbol] Therefore, an input is simply performed and the time spent on the input is remarkably reduced.

In addition, two or more phonemes can be input by performing the skim input once in which the plurality of input keys 11 are touched in the form of streamline.

On the other hand, in this case, a first input key sensor 21 and a second input key sensor 22 can have a plurality of sense lines in a circumferential direction and in a radial direction.

As illustrated in FIG. 16, an internal input key 15 is further provided in the first input keys 11 to assign characters, numbers, signs or various functions.

Here, when the internal input key 15 or the second input key 12 are provided in the first input key 11, the internal input key 15 or the second input key 12 can perform data input such as assigned characters, numbers, and signs, various function input such as mode change, enter, space, and cancel, and a center input function such as combination input of the first input key 11, the second input key 12, and the internal input key 15.

Hereinafter, the above-described center input function can be commonly applied to all of the embodiments of the present specification.

On the other hand, the sensor 20 can have various kinds other than the above-described sense line. For example, in FIG. 17, 5 sense lines are formed in each of the first input keys 11 and the second input keys 12 in a circumferential direction and sense lines of 3 sets are formed in a radius direction so that 15 sense lines are provided in one input unit. However, the arrangement and number of sense lines can vary in accordance with the environment under which the input keys 10 and the sense lines are formed.

As illustrated in FIG. 17, when the plurality of sensors 20 are provided in a circumferential direction and in a radius direction, it is possible to determine an effective signal between the first input key 11 and the second input key 12 and to determine an effective signal between the same first input keys 11.

That is, when a signal is sensed only in the second input key sensor 22 (e1) and when a signal is sensed over the two second input key sensors 22 so that a sense region is inclined to one side, only an input to the second input key 12 is determined to be effective.

Therefore, in the data input device according to one embodiment of the present invention, the plurality of sense lines are provided in each of the input keys 10. Although two or more input keys 10 are sensed, the sense regions are compared with each other to determine the intention of a user so that it is possible to rapidly input data in a narrow space.

That is, although the plurality of input keys 10 are densely arranged in a narrow area, it is possible to prevent the input error caused by ‘interference’ between the input keys 10 using the above-described method.

On the other hand, another example of the present embodiment is illustrated in FIG. 33. Referring to FIGS. 33A and 33B, 8 first input keys 11 are provided outside and 4 second input keys 12 are provided inside.

The characters displayed outside an arc are input by the touch input. The characters displayed in the arc are input by the pressure input. The characters in a square between the first input keys 11 and the second input keys 12 are input by the combination input.

When a word ‘BUS’ is input, an input starts (input ‘S’) in the corresponding position of the first input key 1, ‘U’ is input by the combination input, and restoration is made to the first input key 11 to input ‘S’.

As described above, when, after the third character is input only during predetermined sequential combination and an initial generation signal and an initial signal are generated between the first input keys 11, the first character or the second character is input only in a part where a signal is cancelled or maintained, a word can be rapidly input by performing a streamlined skim operation without performing additional input operations for characters.

The second input key 12 can input by a touch or a pressing, and may be provided to input by touch.

FIG. 33A illustrates an embodiment of the second input key positioned inside, and FIG. 33B illustrates an embodiment of the second key 12 positioned outside.

Even in FIG. 34 described above, if the first character or the second character is inputted only where the initial generating signal and the initial signal are released (terminated) or maintained after the generation, every word can be continuously inputted one by one at a very high speed by one stream skim without additional action for the respective characters.

In a case of providing the first input key 11 and the second input key 12 like this embodiment, since there is no necessity for additionally providing the input keys 10 to which the third characters are assigned by the combination input, the input space can be minimized within the same input capacity.

Two pairs of the data input device according to this embodiment of the present invention are provided to the right and left sides and the upper and lower sides of the input space so that the input capacity can be maximized.

### Third Embodiment

A data input device according to the third embodiment of the present invention further includes the conversion input unit 55 provided adjacent to the plurality of input keys 10 such that the controller extracts the fourth character from the memory and inputs the fourth character due to the sequential input in which the input keys 10 and the conversion input unit 55 are sequentially selected.

Consonant characters may be inputted by the single inputs of the respective input keys 10 and vowel characters may be inputted by the sequential inputs due to the order of the input keys 10 and the conversion input unit 55.

In this case, none of inputs may be performed by the sequential input in reverser order. Other else, vowel characters may be inputted by the sequential input due to the order of the conversion input unit 55 and the input keys 10. Even in this case, none of inputs is performed by the sequential input in the reverse order.

The plurality of input keys 10 may be arranged in a circular form such that the controller can validly extract and input only a character assigned to the input key 10 that is finally selected during the performance of a circumferential input in which the plurality of input keys 10 are sequentially selected in the circumferential direction.

Alternately, the conversion input unit 55 provided at the center of a circle corresponding to the inside of the input keys 10 may be further included. In this case, the controller can extract and input the fourth character from the memory when the internal sequential input of selecting the keys in the order of the first input keys 11 and the conversion input unit 55 or the external sequential input of selecting the keys in the reverse order is performed.

In the respective cases as described above, a direction of the sequential input for inputting the assigned vowel may be marked on any one of the input keys 10 or the conversion input unit 55. Here, two pairs of the input keys 10 or the conversion input unit 55 may be provided according to the input region.

In the respective cases as described above, a direction of the sequential input for inputting the assigned vowel may be marked on any one of the input keys 10 or the conversion input unit 55. Here, two pairs of the input keys 10 or the conversion input unit 55 may be provided according to the input region.

Hereinafter, the data input device according to the third embodiment of the present invention will be described in detail with reference to the accompanying drawings.

The respective input keys 10, like the above-mentioned embodiments, are provided such that one-stage input for inputting the first character and two-stage input for input the second character are independently performed.

The one-stage input and the two-stage input may be implemented by the touch input and the pressure input, or only the multiple pressure inputs. Moreover, in respective cases, the pressure inputs may be more than two-stages (or three stages).

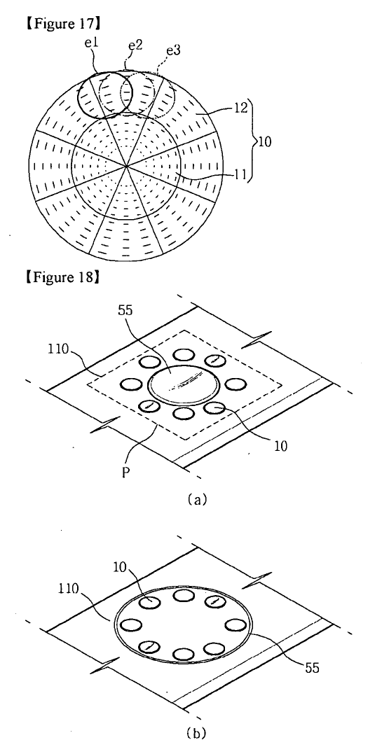

Referring to FIG. 18, the input keys 10 are eight to be radially arranged in the input region P, and each of the input keys 10 may protrude to the same height as or a similar to that of the case 110 to enable the skim input. In this case, the plurality input keys 10 may not be formed individual components by an integrated ring type input key.

In a case of the integrated ring type input keys 10, like the eight input keys, the input keys 10 have direction pressing function in the eight radial directions like the eight input keys. In addition, absolutely, the ring type input keys 10 have a circular shape and a polygonal shape.

Each of the input keys 10 may be assigned by two or more duplicated first characters. This is more effective in a case of a plurality of phonemes like Japanese characters.

In other words, when eight input keys 10 are provided, since sixteen first characters are respectively assigned to the one-stage input and the two-stage input of the input keys and eight fourth characters are assigned by the sequential input of the input keys 10 and the conversion input unit 55, total 24 characters can be assigned.

Therefore, in Korean characters, every phonemes can be arranged without adding the number of the input keys 10 and the multiple input. In a case of a plenty of phonemes such as alphabets, Japanese characters, or Chinese characters, the input capacity can be increased by various ways of adding the input keys 10, the multiple input, or of providing two pairs thereof.

Here, in a case of inputting characters, consonants are assigned to the first characters and vowels are assigned to the fourth characters.

This is to arrange consonants to the input keys 10 for relatively freely increasing the input capacity and vowels to the sequential input, because the number of vowels is less than consonants in every language.

The conversion input unit 55 may be provided at various positions and in various shapes, for example, as illustrated in FIG. 18, inside or outside the input keys 10 in a circular plate or a ring shape.

FIG. 18A illustrates the conversion input unit 55 provided to the inside of the input keys 10 in the circular plate, and FIG. 18B illustrates the conversion input unit 55 provided to the outside of the input keys 10 in the integrated ring type.

FIG. 19 illustrates another embodiment of the data input device according to one embodiment of the present invention in which the input keys 10 are arranged in a rectangular form.

As illustrated, each of the input keys 10 includes two columns of respective four input keys.

The conversion input unit 55 may be arranged at the center of the input keys 10 as illustrated in FIG. 19A, or both sides of the input keys 10 as illustrated in FIG. 19B. Here, in the data input device as illustrated in FIG. 19, the number of the input keys 10 and the number of the arrangement of the input keys 10 can be modified in various ways.

The conversion input unit 55 can be inputted by the fashion such as the touch input, the pressing input, and the touch/pressing input so that can perform functions such as a separate input or a mode change individually, and can be used as an input key of the calling/ending function or the confirmation/cancel input key of a mobile phone.

Alternatively, the conversion input unit 55 can perform the mode change, the menu selection function, the volume controlling function, the cursor moving function, the direction indicating function, or the scrolling function like the input keys 10.

FIG. 20 is a perspective view illustrating another data input device according to the third embodiment of the present invention. As illustrated in the drawing, the input key 10 may include first input keys 1 and a third input keys 13.

The third input key 13 can input data by the combined operation of the first input keys 11 and the conversion input unit 55, and unlikely FIG. 20, an additional individual keys such as the calling/ending key of the mobile phone is provided near to the first input keys 11 or the conversion input unit 55 to perform a function that is frequently performed.

Alternatively, the third input key may be configured such that the first character is inputted by the touch inputs of the first input keys 11 and the fourth character is inputted by the sequential input of the first input keys 11, the conversion input unit 55, and a new character can be inputted by the sequential operation of the first input keys 11 and the third input key 13.

The conversion input unit 55 may be configured such that a character can be inputted by the sequential operation of itself and the input keys 10. Particularly, in a case of further providing the third input key 13, since a plurality of characters, symbols, and numerals can be inputted without changing modes, more rapid input is enabled.

If the third input key 13 were positioned near to the input keys 10 and the conversion input unit 55 to input data due to the operation of the input keys 10 and the conversion input unit 55, the third input key 13 may be fabricated in various types other than those as illustrated in FIGS. 18 to 20.

Two or more duplicated first characters may be assigned to the input keys 10 such that consonants are assigned to the first characters and vowels are assigned to the fourth characters.

Although the positions of the consonants and the vowels are arranged reversers to that as described above according to the inputted characters, in one embodiment, one of the vowels and the consonants with more number and frequently used is inputted by the input keys 10 and the other is inputted by the sequential input of the input keys 10 and the conversion input unit 55.

Moreover, the characters may be arranged in other fashion as described above, and various numerals, symbols, commands as well as the characters may be arranged.

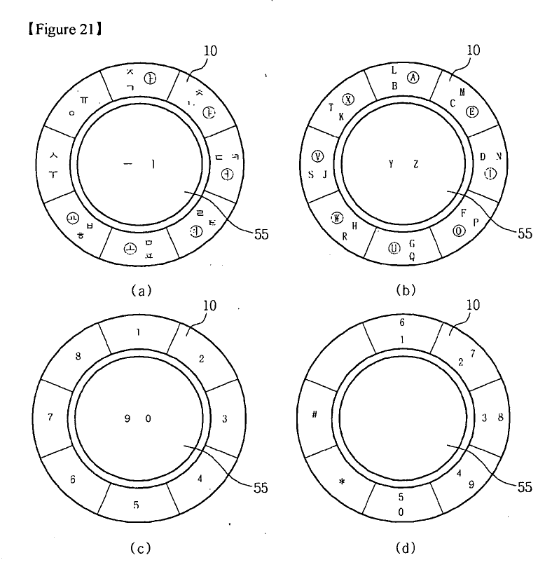

Furthermore, if it is difficult to arrange the entire characters in the arrangement of the input keys 10, as illustrated in FIG. 21, it may enable the input through the touch or the pressure input of the conversion input unit 55.

FIG. 21 illustrates an arrangement of the characters in the data input unit according to this embodiment of the present invention, particularly, the detail arrangement of Korean characters, alphabets, and numerals, respectively.

In a case of the alphabets, as illustrated in FIG. 21B, when eight input keys 10 are provided, sixteen characters are assigned by the one-stage input and two-stage input, eight characters are assigned by the sequential input of the input keys 10 and the conversion input unit 55, and the rest two characters are assigned to the conversion input unit 55 in the form of the touch input and the pressure input.

Alternatively, if the conversion input unit 55 functions any one of the touch input and the pressure input, a method of pressing a key sequentially twice to convert a character is employed, an additional input key is provided to the inside or the outside of the input keys 10 and the conversion input unit, or the touch input, the pressure input, or a tilting function are provided to the right and left sides or the upper and lower sides of the conversion input unit 55.

In a case of Korean characters, [symbol] and [symbol] may be assigned to the additional key.

In the above case, the sense function for inputting the fourth character through the sequential combination of the input keys 10 and the conversion input unit 55, as the original function of the conversion input unit 55 is positioned at the center, and the center may have an additional distinguishable signal.

In this case, the central distinguishable signal is inputted by sequentially touching twice or is implemented by the touch input and the pressure input. The conversion input unit 55 may be used as a function such as the mode change, the confirmation, the cancel, and the calling/ending in the phone mode due to the above-mentioned input operations.

Alternatively, the directional input function of the conversion input unit 55 may be used as the function such as the mode change, the confirmation, the cancel, and the calling/ending in the phone mode.

Moreover, the conversion input unit 55 is provided to a directional movement or a direction pressing so that the conversion input unit 55 can be used as a mouse or a joystick for playing a game.

The sequential input is to input the fourth character due to the sequential selection of the input keys 10 and the conversion input unit 55. the sequential input may be configured such that different signal may be inputted due to the sequence of the input keys 10 and the conversion input unit 55 or a single identical signal may be inputted.

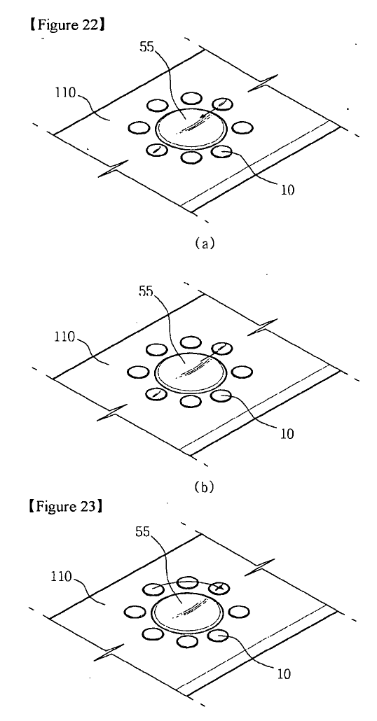

In the former, the sequential input can use both of two types or any one selectively. In other words, only the sequential input in the order of the input keys 10 and the conversion input unit 55 (FIG. 22A) is valid, and the reverse sequential input (FIG. 22B) cannot input any data.

On the other hand, the skim input is enabled in the data input device according to this embodiment of the present invention.

As illustrated in FIG. 23, the circumferential movement enables the skim input. This is to continuously select two or more input keys 10 for input the continuous consonants such as [symbol] In this case, only the initial sensed signal and the finally sensed signal are valid among a plurality of sensed signals.

Here, in a method of determining the final sensing signal, for example, the final sensing signal is determined when, in a case of continuously generating a plurality of sensing signals, the signals are continuously generated without any breaking point even at any one signal and the signals are broken, or when two or more skim inputs are continuously sensed within respective predetermined time intervals and a next signal is not generated after the predetermined time intervals have been lapsed from a predetermined sensing signal.

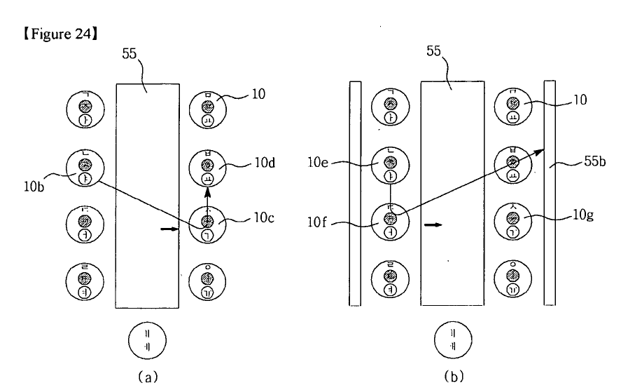

FIG. 24 illustrates a sequential input according to one embodiment of the present invention.

FIG. 24A illustrates an arrangement of Korean characters in which eight input keys 10 are arranged in two columns and an additional key 10a is further provided to assign [symbol] A character assigned to the uppermost side of the respective input keys 10 is the first character inputted by the touch input, a character assigned to the center is the first character inputted by the pressure input, and a character assigned to the lowest side is the fourth character inputted by the sequential input.

A line in FIG. 24A is a line of indicating finger movement to input a Korean character [symbol] such that an input key 10 corresponding to the first character [symbol] is touched to input, [symbol] is inputted by the sequential input of the conversion input unit 55 and the input key 10, and [symbol] is touched to input by the skim input. In this case, the sequential input is performed only by the sequential touches from the conversion input unit 55 to the input key 10c and the sequential input performed by the sequential touches from the input key 10b to the conversion input unit 55 is neglected.

On the other hand, the skim input from the input key 10c to 10d is applied with a method of determining only the final signal valid.

FIG. 24B illustrates an example of using a reverse sequential input. When a Korean character [symbol] is inputted, the input keys 10e assigned with the first character [symbol] is touched, the input key 10f assigned with the third character [symbol] is touched, and continuously the conversion input unit 55 is touched to input [symbol] After that, the input key 10g assigned with the first character [symbol] is pressed so that the input of [symbol] is completed. Like that, in this embodiment, the sequential input from the conversion input unit 55 to the input keys 10 is neglected.

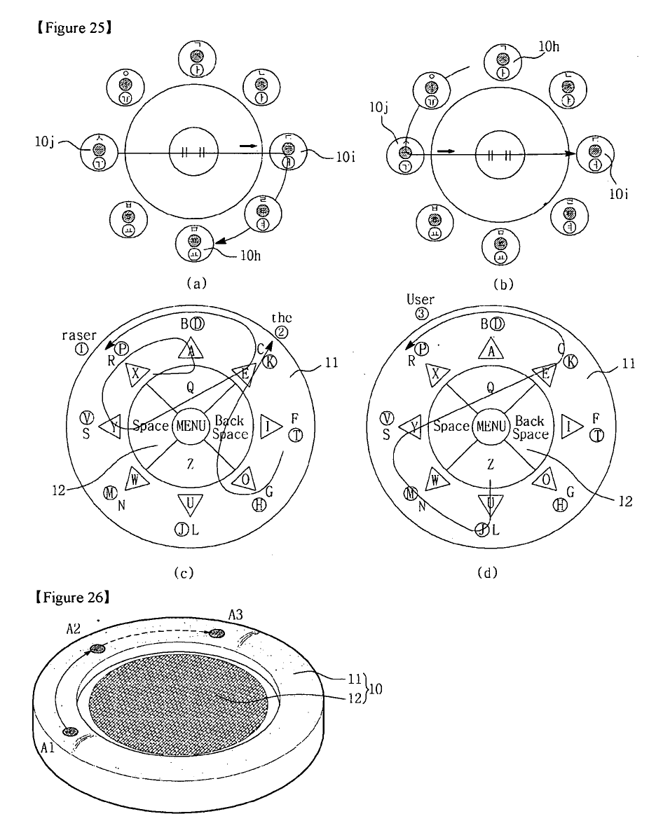

FIG. 25 illustrates an example of an input in the circular arrangement as the embodiment of the present invention. FIG. 25A illustrates a movement of a user for the input of [symbol] As illustrated, the input key 10j is touched to input [symbol] corresponding to the first character, [symbol] is inputted by the sequential input of the conversion input unit 55 and the input key 10i, and the input key 10h is pressed to input [symbol] so that the character [symbol] can be inputted.

In this case, the sequential input from the input key 10j to the conversion input unit 55 is neglected and the single input of the input key 10i in the sequential input from the conversion input unit 55 to the input key 10i is neglected.

On the other hand, FIG. 25B illustrates a movement of a user for the input of [symbol] As illustrated, the input key 10h is touched to input [symbol] corresponding to the first character, the sequential input from the input key 10j to the conversion input unit 55 is performed to input [symbol] by the touch input, and the input key 10i is touched to input

[symbol]

Here, inputs between the respective input keys of the input keys 10 may be configured to input the initial input signal and the final input signal when two or more input keys are continuously inputted.

FIGS. 25C and 25D illustrate an example of inputting alphabets.

Firstly, referring to FIG. 25C, \textcircled{1} indicates a path of a skim input for inputting an English word ‘RASER’, and \textcircled{2} indicates a path of a skim input for inputting an English word ‘THE’.

The method of determining the final input signal is identical to the above description. When a finger is released from the input key for the final input during the skim input (skimming), a character inputted by the touch input is inputted, and a character at the pressure input is inputted when the finger is released after the pressure input.

Due to this, the user simultaneously inputs the consonants and the vowels (without additional input operation) and can input other characters by the skim input within the input keys so that the user can input a character with a single stream operation without individually touching or pressing the respective input keys.

In other words, when sequentially inputting a consonant-a vowel-a consonant, the user selects a consonant to be inputted from the input keys 10 through the touch input or the pressure input, a vowel to be secondly inputted by touching the input keys 10 via the conversion input unit 55 (touch input), and thirdly a consonant to be inputted through the input keys 10 by the touch input or the pressure input.

In this case, although the third consonant can be inputted by an individual operation after the second vowel, the third consonant may be continuously input simultaneously with inputting the second vowel by the skim input as described above.

In other words, in the input method according to one embodiment of the present invention, the input can be completed not by individually inputting consonant-vowel or consonant-vowel-consonant but by the single stream skim input.

The majority of languages consist of consonants and vowels, most words consist of consonant-vowel or consonant-vowel-consonant, a single word has an average 4.7 phonemes.

Thus, when characters are inputted using the input method according to one embodiment of the present invention, a single character to a single word can be very rapidly and conveniently inputted by a single stream skimming operation. In addition to the consonants -vowels and the consonant-vowel-consonant, words in the form of consonant-consonant-vowel, vowel-vowel-consonant, vowel-consonant-vowel, and vowel-consonant-consonant can be inputted by the method as described above.

In the above-mentioned respective embodiments, as illustrated in FIGS. 24 and 25, any one of the conversion input unit 55 and the input keys 10 may be marked with an arrow of indicating a direction of the sequential input.

### Fourth Embodiment

A data input device according to the fourth embodiment of the present invention includes a plurality of input keys 10 arranged in a circular shape in which respective input keys 10 are assigned with duplicated fifth characters such that the controller extracts the fifth characters from the memory to input when an event input is sensed.

The event input may be provided in various types, for example, an operation which a finger is released from a predetermined input key 10 during the skim input to release the touch sensing signal. In other words, this is caused by a signal release at the input key 10, for example, can be distinguished by the difference between sensed time, sensed currents or sensed pressures.

Referring to FIG. 26, the event input using the signal releasing method will be described. A first character assigned to a corresponding input key is inputted when a user touches a part of the input key 10, and the event input is determined when the input is continued while a plurality of input keys 10 are skimmed in the circumferential direction and a finger is released to release the signal, so that a fifth character instead of the first character assigned to the corresponding position is inputted.

In the event input due to the different of sensing time, when the first character is inputted at a position A1, the skim input is performed via a position A2, and a sensing signal is continued at a position A3 for a time longer than a predetermined time, the controller determines this as the event input to input the fifth character assigned to the position A3.

Needless to say, if the sensing time at the position A 2 is less than the predetermined time, instead of the fifth character, the first character assigned to the position A2 is inputted.

The event input due to the difference of the sensing time can be performed at the intermediate stage of the skim input, for example, when a finger stays at the position A2 for a time longer than the predetermined time during the skim input from the position A1 to the position A3, the fifth character assigned to the position A2 is inputted.

Therefore, in this case, the first character assigned to the position A1, the fifth character assigned to the position A2, and the first character assigned to the position A3 are sequentially inputted.

The event input can be processed by several variations of signals such as pressure, static electricity capacity, and etc. other than the maintenance or release of a signal.

Alternatively, the event input can be performed by pressing side of the input keys in the transversal direction of the pressing directions of the input keys 10. Alternatively, the event input can be performed by changing the direction of the skimming that is performed by the respective input keys 10. In other words, the touches or the skimming in the circumferential direction of the respective input keys 10 is a single input, and the skimming in the radial direction is the event input.

In this case, the touch sensor 30 includes a first touch sensor 30a for sensing touches or the skims in the circumferential direction of the respective input keys 10 and a second touch sensor 30b for sensing the skim in the radial direction of the respective input keys 10.

Alternatively the event input may be configured such that a vowel is inputted and after that a consonant is inputted when the event input is generated during the moving touch in the circumferential direction.

On the other hand, in the event input, in order to input consonant and vowel duplicatively assigned to a predetermined input key 10, a method of maintaining a touch on a corresponding input key 10 for a predetermined time.

For example, in a case of assigning [symbol] assigned as the first character to the input key 10 by the touch and of assigning [symbol] as the fifth character by the event input, since [symbol] cannot be inputted by the skim input on the identical input key 10, initially a corresponding input key 10 is touched to input [symbol] and the touched state is maintained for a predetermined time to additionally input [symbol] so that the character [symbol] can be inputted.

The input keys 10, as illustrated in FIGS. 26 to 28, include a first input key 11 arranged in a circular shape and a second input key 12 adjacent to the inside or the outside of the first input key 11.

Referring to FIG. 26, the second input key 12 is provided inside the first input key 11 with an integrated ring shape.

The first input key 11 includes a rolling device such as a bearing disposed in the lower side to be rotated in the circumferential direction.

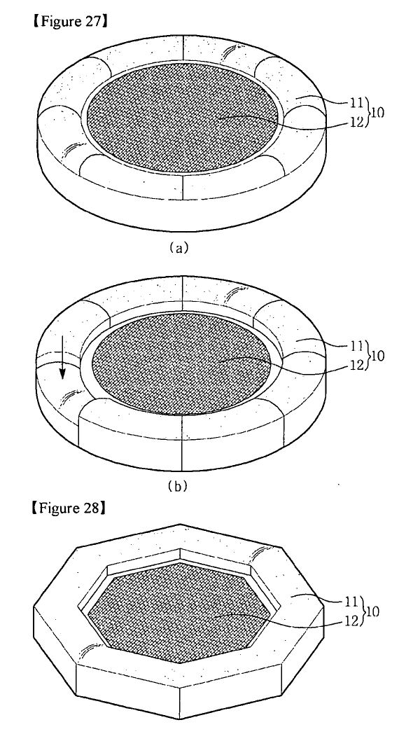

FIG. 27 illustrates a plurality of individually provided first input keys 11 that are arranged in the circular shape. In this case, as illustrated in FIG. 27B, the respective first input keys 11 can be individually selected so that the user more conveniently feels a precise click in comparison to the integrated type.

On the other hand, the first input keys 11 may be arranged in various types, for example, as illustrated in FIGS. 26 and 27, in the circular shape, and as illustrated in FIG. 28, in the polygonal shape. The first input keys 11 may be also arranged in the rectangular shape like the above-mentioned embodiment.

On the other hand, in a case of arranging the first input keys 11 in the circular shape or the polygonal shape, the first input keys 11 can performed the function such as a mouse scroll or a volume control due to a signal sensed in the circumferential direction.

The second input key 12, as illustrated in FIGS. 26 to 28, may be provided inside the first input keys 11 in the circular plate or outside the first input keys 11 in the ring shape.

The first input keys 11 and the second input key 12 may be provided in various shapes and arrangements other than the above-mentioned embodiments without any limit.

The controller can extract a third character different from a character initially assigned to the corresponding input key 10 from the memory to input when a combined input of simultaneously selecting the first input keys 11 and the second input key 12 within a predetermined time is performed.

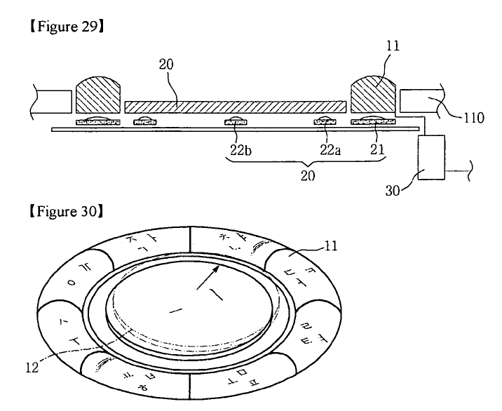

FIG. 29 is a sectional view illustrating the data input device according to this embodiment of the present invention. Referring to FIG. 29, the first input keys 11 with a ring shape are provided outside, the second input key 12 with a circular plate is provided inside the first input keys 11, and a first input key sensor 21 for sensing the pressure input is provided in the lower sides of the first input keys 11. Here, a touch sensor 30 may be further provided to sense the touch input on the first input keys 11.

The first input keys 11 and the second input key 12, as described above, are provided to independently perform the one-stage input and the two-stage input such that the one-stage is the touch input and the two-stage is the pressure input, or both of the one-stage input and the two-stage is the pressure input.

When the second input key 12, as illustrated in FIGS. 26 to 29, is provided inside the first input keys 11 in the circular plate, the center and the edge of the second input key 12 distinguishes and senses two signals.

The second input key 12 is provided to perform the touch input/pressure input or the one-stage pressure input/two-stage pressure input in the radial direction (e.g., four or eight directions).

Other than the four directions, east, west, south, and north, the touch input/pressure input or the one-stage pressure input/two-stage pressure input may be added according to the size of the first input keys 11 and the circumstance of use.

The second input key 12 may include a touch pad function or a touch screen function, enable a horizontal movement in the radial direction, and perform a mouse function through the touch pad or the horizontal movement. In this case, the function of the right and left buttons of a mouse can be performed by the input on the edge. Alternatively, a function of character reading of cursive script can be performed through the second input key 12.

The above-mentioned functions are not limited by this embodiment but can be applied to other embodiments without limit.

Even in a case of providing the second input key 12 outside the first input keys 11 in the ring shape, the one-stage input and the two-stage input are enabled.

The one-stage input and the two-stage input are assigned with characters, numerals, symbols, or various function commands, for example, in a case of inputting Korean characters, [symbol] ┐′ may be assigned.

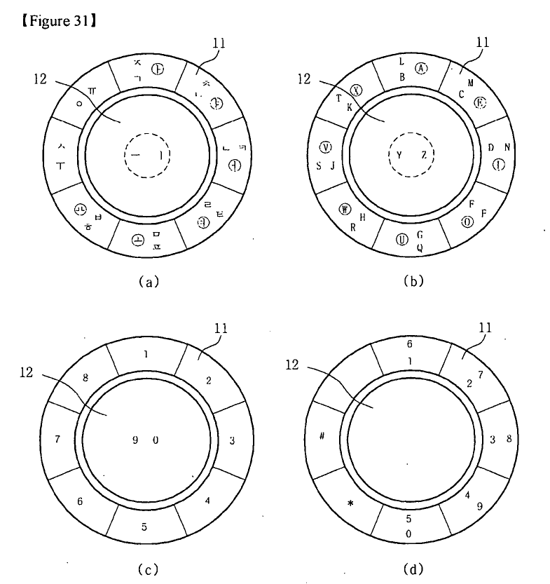

Other than those, the second input key 12 may perform a mode change and a cursor movement at character input. Alternatively, as illustrated in FIG. 30, due to the directional movement of the second input key 12, a mouse pointer moves, numerals or symbols are inputted, various command keys such as various mode changes, an enter key, a space key, a cancel key, and a cursor movement can be inputted.

In this case, a movement sensor (not shown) for sensing the radial movement of the second input key 12 is further provided, and the controller extracts a sixth character assigned to a corresponding radial direction where the movement of the second input key 12 is sensed from the memory to input.

Although the second input key does not move, the sixth character assigned to the touch movement performed by the second input key 12 can be inputted according to the direction of the touch movement. In this case, the touch sensor 30 must be provided to sense the movement direction of the touch.

FIG. 31 illustrates an arrangement of Korean characters, English characters, and numerals event of the data input device according to this embodiment of the present invention. Firstly, in a case of Korean characters as illustrated in FIG. 31A, consonants (first characters) with a large number and frequently used the number are duplicatively assigned to the first input keys 11 and vowels (fifth characters) inputted by the event input are marked within a circle.

The characters duplicatively assigned to the first input keys 11 are respectively distinguished and inputted by the one-stage input and the two-stage input. Korean vowel [symbol] are assigned to the second input key 12. For example, the first characters inputted by the one-stage input are [symbol] [symbol] the first characters inputted by the two-stage input are [symbol] [symbol] and the third characters inputted by the event input are

[symbol]

[symbol]

In a case of the numerals arranged with a small number, as illustrated in FIGS. 31C and 31D, the numerals may be duplicatively assigned only to the first input keys 11 or to the first keys 11 or the second key 12 one by one.

The arrangements of the first input keys 11 and the second input key 12 and the arrangement of the characters can be modified in various fashions. For example, when the one-stage inputs are the touch inputs (characters relatively near the center) and the two-stage inputs are the pressure inputs (characters relatively farther from the center), the input of [symbol] will be described as follows.

Firstly, a first input key 11 corresponding to [symbol] is pressed, the second input key 12 is touched to input [symbol] and a part of the first input key 11 corresponding to [symbol] is touched to input

[symbol]

Next, a specific part of the first input key 11 corresponding to [symbol] is pressed, a signal is maintained during the skimming along the circumferential direction of the first input key 11, and the signal is broken at a position corresponding to [symbol] to perform the event input.

Finally, a specific part of the first input key 11 corresponding to [symbol] is pressed, a signal is maintained during the skimming along the circumferential direction of the first input key 11, the event input is performed by breaking the signal at the position of [symbol] and a part of the first input key 11 corresponding to [symbol] is touched to complete the input of

[symbol]

FIG. 32 is a perspective view of a mobile communication terminal 100 in which the data input device is mounted.

The data input device can be applied to various informational devices for inputting data as well as the mobile communication terminal 100. According to one embodiment of the present invention, since data is inputted by sensing a conversion signal, repeated input is prevented and operations caused by the user can be reduced so that a great deal of data can be rapidly and precisely inputted.

Two pairs of the data input devices may be provided at the lateral sides of the case 110 of the mobile communication terminal 100.

In one embodiment, since a single input key can independently perform the one-stage input and the two-stage input, the input capacity can be increased by two times.

Moreover, times of operations for selecting characters which are dupulicatively assigned to the input keys in the conventional art can be reduced by an half, the input time is reduced and the user conveniently uses.

The respective input keys are grouped into vowel input key sets and consonant input key sets such that the vowel input key sets are disposed between the consonant input key sets.

Therefore, since the consonant and the vowel or the consonant, the vowel, and the consonant are continuously inputted through a shortest path using the sequential operation, the speed of inputting characters can be minimized and precise input is enabled.

Since a great deal of data can be inputted within a narrow regions by simultaneously using the first input keys and the second input key, and the repeated operation is unnecessary due to the sequential input operations to prevent malfunction due to carelessness of the user, the precise input of data is enabled.

The data input device may provide convenience for inputting data due to the simple configuration and using method, is applied to various information devices so that the information devices can be light in weight and minimized.

In one embodiment, a great deal of data can be inputted within a narrow space due to the sequential operation of the first and second input keys, and the repeated operation is unnecessary due to the sequential input, so that malfunction caused by the carelessness of the user can be prevented and a great deal of data can be inputted.

Moreover, new data is inputted by the event input so that a great deal of data can be inputted within a narrow space. Since the repeated operation is unnecessary due to the sequential input to prevent the malfunction caused by the carelessness of the user, the precise input of data is enabled.

Although a few embodiments of the present invention have been shown and described, it would be appreciated by those skilled in the art that changes might be made in this embodiment without departing from the principles and spirit of the invention, the scope of which is defined in the claims and their equivalents.

According to at leas one embodiment, since a single input key can independently perform the one-stage input and the two-stage input, the input capacity can be increased by two times.

Moreover, times of operations for selecting characters which are dupulicatively assigned to the input keys in the conventional art can be reduced by an half, the input time is reduced and the user conveniently uses.

The respective input keys are grouped into vowel input key sets and consonant input key sets such that the vowel input key sets are disposed between the consonant input key sets.

Furthermore, since the consonant and the vowel or the consonant, the vowel, and the consonant are continuously inputted through a shortest path using the sequential operation, the speed of inputting characters can be minimized and precise input is enabled.

Since a great deal of data can be inputted within a narrow regions by simultaneously using the first input keys and the second input key, and the repeated operation is unnecessary due to the sequential input operations to prevent malfunction due to carelessness of the user, the precise input of data is enabled.

The data input device may provide convenience for inputting data due to the simple configuration and using method, is applied to various information devices so that the information devices can be light in weight and minimized.

According to at leas one embodiment, a great deal of data can be inputted within a narrow space due to the sequential operation of the first and second input keys, and the repeated operation is unnecessary due to the sequential input, so that malfunction caused by the carelessness of the user can be prevented and a great deal of data can be inputted.

Moreover, new data is inputted by the event input so that a great deal of data can be inputted within a narrow space. Since the repeated operation is unnecessary due to the sequential input to prevent the malfunction caused by the carelessness of the user, the precise input of data is enabled.

Although a few embodiments of the present invention have been shown and described, it would be appreciated by those skilled in the art that changes might be made in this embodiment without departing from the principles and spirit of the invention, the scope of which is defined in the claims and their equivalents.

1. A data input device, comprising:
a plurality of input keys in which a one-stage input for inputting a first character and a two-stage input for inputting a second character are independently performed;
a sensor configured to sense the one-stage input and the two-stage input to the input keys; and
a controller configured to extract the first character or the second character redundantly assigned to the corresponding input key based on the sense result of the sensor from a memory to input the first character or the second character.

2-7. (canceled)

8. The data input device as claimed in claim 1,
wherein predetermined consonants and vowels are simultaneously assigned to the input keys,
wherein a conversion input unit for making a conversion into the vowels by the input keys and the combination input is further provided, and
wherein the conversion input unit is provided in at least one of inside and outside of the input keys.

9-11. (canceled)

12. The data input device as claimed in claim 1,
wherein the one-stage input is a touch input performed by contacting or approaching the input keys,
wherein the two-stage input is a pressure input in which the input keys move up and down,
wherein the sensor comprises:
a touch sensor for sensing the touch input; and
a pressure sensor for sensing the pressure input, and
wherein a skim input in which two or more input keys sequentially contact can be performed in the touch input.

13. The data input device as claimed in claim 12, further comprising a conversion input unit provided to be adjacent to the plurality of input keys
wherein the controller extracts a fourth character from a memory by a sequential input of sequentially selecting the input key and the conversion input unit to input the fourth character.

14-15. (canceled)

16. The data input device as claimed in claim 1,
wherein the input key comprises:
a first input key; and
a second input key provided to be adjacent to inside or outside of the first input key, and
wherein, when a combination input of simultaneously selecting the first input key and the second input key within predetermined time is performed, a third character different from the character originally assigned to the corresponding input key is extracted from a memory to be input.

17. (canceled)

18. The data input device as claimed in claim 16, the plurality of sensors are provided in each of the first input key and the second input key.

19. The data input device as claimed in claim 16, wherein the controller determines only a signal maintained for no less than predetermined time as an effective signal among the sense signals of the first input key and the second input key sensed by the sensors to perform an input.

20. (canceled)

21. The data input device as claimed in claim 1, further comprising a conversion input unit provided to be adjacent to the plurality of input keys,
wherein the controller extracts a fourth character from a memory by a sequential input of sequentially selecting the input key and the conversion input unit to input the fourth character.

22. The data input device as claimed in claim 21,
wherein a first character or a second character is input by a single input of the input key,
wherein a fourth character is input by a sequential input in the order of the input key and the conversion input unit or the conversion input and the input key, and
wherein an input is not performed by the sequential input in the opposite order.

23. (canceled)

24. The data input device as claimed in claim 21,
wherein the plurality of input keys are circularly arranged, and
wherein, when a circumferential input in which a plurality of input keys are sequentially selected along a circumferential direction is performed, the controller determines only the character assigned to the finally selected input key to be effective so that an input is performed.

25. The data input device as claimed in claim 1,
wherein the one-stage input is a touch input performed by contacting or approaching the input keys,
wherein the two-stage input is a pressure input in which the input keys move up and down,
wherein the sensor comprises:
a touch sensor for sensing the touch input; and
a pressure sensor for sensing the pressure input,
wherein the plurality of input keys are circularly arranged and include another touch sensors for sensing skimming in the radius direction of the input keys,
wherein a first character or a second character is input by the touch input or a pressure input, and
wherein a fourth character is input by radius direction touch to the input key.

26. The data input device as claimed in claim 22, wherein the direction of the sequential input for inputting the assigned fourth character is displayed in the input key.

27. (canceled)

28. The data input device as claimed in claim 21,
wherein the one-stage input is a touch input performed by contacting or approaching the input keys,
wherein the two-stage input is a pressure input in which the input keys move up and down,
wherein the sensor comprises:
a touch sensor for sensing the touch input; and
a pressure sensor for sensing the pressure input,
wherein the plurality of input keys are circularly arranged,
wherein a fifth character is redundantly assigned to the input key, and
wherein, when an event input is sensed, the controller extracts the fifth character from a memory to input the fifth character.

29. The data input device as claimed in claim 28, wherein the event input is performed by lifting a finger from a predetermined input key during the skim input so that a touch sense signal is canceled or by continuously generating a touch sense signal to a predetermined input key for no less than predetermined time.

30. The data input device as claimed in claim 1, wherein the event input is performed by horizontally pressing a side in the pressure direction of the input key.

31. The data input device as claimed in claim 1,
wherein the touch sensor comprises:
a first touch sensor for sensing touch to the input key or skimming in a circumferential direction; and
a second touch sensor for sensing skimming to the radius direction to the input key,
wherein the controller extracts the first character when the sense signal of the first touch sensor is received and the fifth character determined to be an event input when the sense signal of the second touch sensor is received to input the first character and the fifth character.

32. The data input device as claimed of claim 28,
wherein the input key comprises:
a circularly arranged first input key; and
second input keys provided to be adjacent to the inside or the outside of the first input key, and
wherein, when a combination input of simultaneously selecting the first input key and the second input key within predetermined time is performed, the controller extracts a third character different from the character originally assigned to the corresponding input key from a memory to input the third character.

33. The data input device as claimed in claim 32, wherein the second input key can be moved in a predetermined radial direction and further comprises a movement sensor for sensing the radial movement of the second input key, and
wherein the controller extracts a sixth character assigned in the corresponding radial direction where the movement of the second input key is sensed from a memory to input the sixth character.

34. The data input device as claimed in claim 1,
wherein the second input key can be moved in a predetermined radial direction and further comprises a movement sensor for sensing the radial movement of the second input key, and
wherein the controller extracts a sixth character assigned in the corresponding radial direction where the movement of the second input key is sensed from a memory to input the sixth character.

35. The data input device as claimed in claim 1,
wherein the touch sensor is provided to sense touch movement to the radial direction to the second input key, and
wherein the controller extracts a sixth character assigned in the corresponding radial direction in the direction of touch movement performed by the second input key from a memory to input the sixth character.

36. The data input device as claimed 1,
wherein the two pairs of first input keys, second input keys, and sensors are provided in the input region,
wherein the two pairs of input keys, conversion input units, and sensors are provided in the input region, and
wherein the plurality of two pairs of input keys and sensors are provided in the input region.

37-43. (canceled)

44. A data input device, comprising:
a plurality of input keys in which a one-stage input for inputting a first character and a two-stage input for inputting a second character are independently performed;
means for sensing the one-stage input and the two-stage input to the input keys; and
means for extracting the first character or the second character redundantly assigned to the corresponding input key based on the sense result of the sensor from a memory to input the first character or the second character.
